(19) United States
(12) Patent Application Publication
(10) Pub. No.: US 2015/0232746 A1
(43) Pub. Date: Aug. 20, 2015

(54) FILM-FORMING INK, DISCHARGE INSPECTION METHOD, DISCHARGE INSPECTION APPARATUS, METHOD FOR MANUFACTURING LIGHT EMITTING ELEMENT, LIGHT EMITTING ELEMENT, LIGHT EMITTING APPARATUS, AND ELECTRONIC EQUIPMENT

(71) Applicant: SEIKO EPSON CORPORATION, Tokyo (JP)

(72) Inventors: Takuya SONOYAMA, Fujimi-machi (JP); Koji IMAMURA, Kai-shi (JP)

(21) Appl. No.: 14/620,723

(22) Filed: Feb. 12, 2015

(30) Foreign Application Priority Data
Feb. 14, 2014 (JP) 2014-027030

(51) Int. Cl. C09K 11/06; C09K 11/02; G01N 21/95; H01L 51/56; H01L 51/50

(52) U.S. Cl. CPC C09K 11/06; H01L 51/56; H01L 51/5056; H01L 51/5088; G01N 21/95; C09K 11/025; C09K 2211/185; H01L 51/0035

(57) ABSTRACT

A film-forming ink includes a film-forming material which is a material which configures a hole transport layer or a hole injection layer which is included in an organic electroluminescence element, or a precursor thereof, and a liquid medium for dispersing or dissolving the film-forming material, in which an indicator material which emits light by being irradiated with excitation light is added to the film-forming material.

### BACKGROUND

1. Technical Field

The present invention relates to a film-forming ink, a discharge inspection method, a discharge inspection apparatus, a method for manufacturing a light emitting element, a light emitting element, a light emitting apparatus, and electronic equipment.

2. Related Art

A method for forming a film by supplying (coating) a film-forming ink formed by dissolving a film-forming material in a solvent onto a base material using a liquid droplet discharging method and removing (drying) the solvent from the film-forming ink on the base material has been put into practical use.

The liquid droplet discharging head used in this method is generally provided with a plurality of nozzle openings and discharges the film-forming ink as liquid droplets from individual nozzle openings. For this reason, the film-forming ink is exposed to the atmosphere at the nozzle openings and the solvent component of the film-forming ink is evaporated through the meniscus (the free surface of the liquid exposed at the nozzle openings). The evaporation of the solvent component leads to an increase in the concentration of the other components in the film-forming ink, causes bending or the like in the flight of the liquid droplets, or generates clogging in the nozzle openings. In addition, when the nozzle openings are in the clogged state, since it is not possible to discharge the liquid droplets from the nozzle openings, there is a concern that it will not be possible to obtain the desired characteristics when forming the film.

Therefore, detection of the presence or absence of missing dots is performed in order to obtain the desired performance. For example, as disclosed in JP-A-2012-187497, a coating region is observed by coating liquid droplets on a receiving layer side of a transparent substrate provided with a receiving layer, irradiating light from one surface side with respect to the substrate, and measuring light spectroscopy from the other surface side.

However, the film-forming ink used when forming a hole transport layer or a hole injection layer using a liquid phase process generally has an extremely low concentration of the film-forming material and has hardly any color. Therefore, even when simply observing the coated film-forming ink using the method described above, it is difficult to measure (recognize) the coating state thereof (in particular, a boundary section between a coating region and a non-coated region). Moreover, in recent years, as the definition of displays has become higher, the definition of the nozzles of the liquid droplet discharging head used in the liquid phase process has also increased, and thus the discharge amount of the liquid droplets discharged at one time is extremely small and it is more and more difficult to measure the coating state.

### SUMMARY

An advantage of some aspects of the invention is that it provides a film-forming ink, discharge inspection method, and a discharge inspection apparatus which are able to perform inspection (discharge inspection) of the liquid droplet discharging head with high precision even when a film-forming ink is not colored with a high concentration or has a high wetting and spreading property with respect to a discharge target, and to provide a method for manufacturing a light emitting element, a light emitting element, a light emitting apparatus, and electronic equipment using the film-forming ink.

The invention can be realized in the following forms or application examples.

### Application Example 1

According to an aspect of the invention, there is provided a film-forming ink including a film-forming material which is a material which configures a hole transport layer or a hole injection layer which is included in an organic electroluminescence element, or a precursor thereof, and a liquid medium for dispersing or dissolving the film-forming material, in which an indicator material which emits light by being irradiated with excitation light is added to the film-forming material.

According to this film-forming ink, since the indicator material emits light by being irradiated with excitation light, it is possible to measure the light emitting state and to recognize the coated state of the film-forming ink with high precision based on the measuring results. Accordingly, it is possible to perform inspection (discharge inspection) of the liquid droplet discharging head with high precision even when the film-forming ink is not colored with a high concentration.

Here, in general, the film-forming ink used when forming a hole transport layer or a hole injection layer using a liquid phase process has an extremely low concentration of the film-forming material and has hardly any color. Therefore, even when simply observing the coated film-forming ink, it is difficult to measure (recognize) the coating state thereof (in particular, a boundary section between a coating region and a non-coated region). Moreover, in recent years, as the definition of displays has become higher, the definition of the nozzles of the liquid droplet discharging head used in the liquid phase process has also increased, and thus the discharge amount of the liquid droplets discharged at one time is extremely small and it is more and more difficult to measure the coating state. Accordingly, by applying the invention to the film-forming ink, the effect thereof is remarkable.

### Application Example 2

With the film-forming ink according to the aspect of the invention, a light emitting function of the indicator material may be eliminated or reduced when the hole transport layer or the hole injection layer is formed.

Due to this, when manufacturing the light emitting element using a hole transport layer or a hole injection layer formed using the film-forming ink, it is possible to prevent the indicator material having an adverse influence on characteristics of the light emitting element.

### Application Example 3

With the film-forming ink according to the aspect of the invention, the light emitting function of the indicator material may be eliminated or reduced due to heating.

When forming the hole transport layer or the hole injection layer using the liquid phase process, in general, a heating treatment (firing) is performed with respect to the coated film-forming ink. Accordingly, it is possible to eliminate or reduce the light emitting function of the indicator material using the heat of the heating treatment.

### Application Example 4

With the film-forming ink according to the aspect of the invention, the excitation light may be ultraviolet light.

Due to this, it is possible to efficiently excite the indicator material.

### Application Example 5

With the film-forming ink according to the aspect of the invention, the light emitted from the indicator material may be visible light or infrared light.

Due to this, it is possible to efficiently measure the light emitting state of the indicator material.

### Application Example 6

According to another aspect of the invention, there is provided a discharge inspection method including coating a recording medium by discharging the film-forming ink according to above-described aspect of the invention thereon as liquid droplets using a liquid droplet discharging head, and irradiating the film-forming ink on the recording medium with excitation light and measuring a light emitting state of the indicator material, in which inspection of the liquid droplet discharging head is performed based on the measuring results.

According to such a discharge inspection method, since the indicator material emits light by being irradiated with excitation light, it is possible to measure the light emitting state and to recognize the coated state of the film-forming ink with high precision based on the measuring results. Accordingly, it is possible to perform inspection (discharge inspection) of the liquid droplet discharging head with high precision even when the film-forming ink is not colored with a high concentration or has a high wetting and spreading property (where bleeding occurs easily) with respect to the recording medium.

### Application Example 7

According to still another aspect of the invention, there is provided a discharge inspection method including coating a recording medium by discharging a film-forming ink, which includes an indicator material which emits light by being excited with excitation light, thereon as liquid droplets using a liquid droplet discharging head, and irradiating the film-forming ink on the recording medium with the excitation light and measuring a light emitting state of the indicator material, in which inspection of the liquid droplet discharging head is performed based on the measuring results.

According to such a discharge inspection method, since the indicator material emits light by being irradiated with excitation light, it is possible to measure the light emitting state and to recognize the coated state of the film-forming ink with high precision based on the measuring results. Accordingly, it is possible to perform inspection (discharge inspection) of the liquid droplet discharging head with high precision even when the film-forming ink is not colored with a high concentration.

### Application Example 8

With the discharge inspection method according to an aspect of the invention, the recording medium may have transmissivity with respect to the excitation light.

Due to this, it is possible to irradiate the film-forming ink on the recording medium with the excitation light via the recording medium.

### Application Example 9

With the discharge inspection method according to an aspect of the invention, the recording medium may not emit light due to the excitation light, or may emit light at a wavelength which is different to the indicator material due to the excitation light.

Due to this, it is possible to efficiently measure the light emitting state of the indicator material.

### Application Example 10

According to still another aspect of the invention, there is provided a discharge inspection apparatus which inspects a liquid droplet discharging head which discharges the film-forming ink according to an aspect of the invention onto a recording medium as liquid droplets, the discharge inspection apparatus including a light emitting section which emits the excitation light which is irradiated onto the recording medium, and a measuring section which measures a light emitting state of the indicator material due to the excitation light on the recording medium, in which inspection of the liquid droplet discharging head is performed based on the measuring results of the measuring section.

According to this discharge inspection apparatus, since the indicator material emits light by being irradiated with excitation light, it is possible to measure the light emitting state and to recognize the coated state of the film-forming ink with high precision based on the measuring results. Accordingly, it is possible to perform inspection (discharge inspection) of the liquid droplet discharging head with high precision even when the film-forming ink is not colored with a high concentration.

### Application Example 11

According to still another aspect of the invention, there is provided a discharge inspection apparatus which inspects a liquid droplet discharging head which discharges a film-forming ink, which includes an indicator material which emits light by being excited with excitation light, onto a recording medium as liquid droplets, the discharge inspection apparatus including a light emitting section which emits the excitation light which is irradiated onto the recording medium, and a measuring section which measures a light emitting state of the indicator material due to the excitation light on the recording medium, in which inspection of the liquid droplet discharging head is performed based on the measuring results of the measuring section.

According to this discharge inspection apparatus, since the indicator material emits light by being irradiated with excitation light, it is possible to measure the light emitting state and to recognize the coated state of the film-forming ink with high precision based on the measuring results. Accordingly, it is possible to perform inspection (discharge inspection) of the liquid droplet discharging head with high precision even when the film-forming ink is not colored with a high concentration.

### Application Example 12

According to still another aspect of the invention, there is provided a method for manufacturing a light emitting element including coating the film-forming ink of the invention onto a base material, and forming a hole transport layer or a hole injection layer by curing or solidifying the film-forming ink.

According to this method for manufacturing a light emitting element, it is possible to perform the inspection of the liquid droplet discharging head, which is used in the coating of the film-forming ink for forming the hole transport layer or the hole injection layer, with high precision. Therefore, it is possible to form the hole transport layer or the hole injection layer with high precision and, as a result, it is possible for the characteristics of the obtained light emitting element to be excellent.

### Application Example 13

With the method for manufacturing the light emitting element according to an aspect of the invention, the light emitting function of the indicator material may be eliminated or reduced when forming the hole transport layer or the hole injection layer.

Due to this, it is possible to prevent the indicator material from having an adverse influence on the characteristics of the obtained light emitting element. Not only that, but the indicator material with a reduced or eliminated light emitting function exhibits a hole transporting property or a hole injection property, and it is also possible to improve the characteristics of the light emitting element.

### Application Example 14

According to still another aspect of the invention, there is provided a light emitting element including a hole transport layer or a hole injection layer formed using the method for manufacturing a light emitting element of the invention.

Due to this, it is possible to provide a light emitting element having excellent characteristics.

### Application Example 15

According to still another aspect of the invention, there is provided a light emitting apparatus including the light emitting element of the invention.

Due to this, it is possible to provide a light emitting apparatus having excellent characteristics.

### Application Example 16

According to still another aspect of the invention, there is provided electronic equipment including the light emitting element of the invention.

Due to this, it is possible to provide electronic equipment provided with a light emitting element having excellent characteristics.

### BRIEF DESCRIPTION OF THE DRAWINGS

The invention will be described with reference to the accompanying drawings, wherein like numbers reference like elements.

FIG. 1A is a perspective diagram which shows a schematic configuration of a liquid droplet discharging apparatus which is provided with a discharge inspection apparatus according to an embodiment of the invention, FIG. 13 is a schematic planar diagram which shows an arrangement of liquid droplet discharging heads, and FIG. 1C is a cross-sectional diagram which shows a schematic configuration of a main section of the liquid droplet discharging head.

FIGS. 2A and 2B are diagrams which schematically show a schematic configuration of a discharge inspection apparatus which is provided with the liquid droplet discharging apparatus shown in FIGS. 1A to 1C.

FIGS. 3A and 3B are diagrams which schematically show a schematic configuration of a modification example of the discharge inspection apparatus which is provided with the liquid droplet discharging apparatus shown in FIGS. 1A to 1C.

FIG. 4 is a block diagram which shows a control system of the liquid droplet discharging apparatus shown in FIGS. 1A to 1C.

FIGS. 5A to 5C are diagrams which illustrate a discharge inspection method (an example of the discharge inspection method of the invention) using the discharge inspection apparatus shown in FIGS. 2A and 2B.

FIG. 6 is a planar diagram which shows an example of a test pattern in the discharge inspection method shown in FIGS. 5A to 5C.

FIGS. 7A to 7D are diagrams which illustrate a film-forming method using the liquid droplet discharging apparatus shown in FIGS. 1A to 1C.

FIG. 8 is a cross-sectional diagram which shows a light emitting apparatus (a display apparatus) according to an embodiment of the invention.

FIG. 9 is a cross-sectional diagram of a light emitting element which is provided in the light emitting apparatus shown in FIG. 8.

FIG. 10 is a perspective diagram which shows a configuration of a portable (or a notebook) personal computer which is an example of electronic equipment of the invention.

FIG. 11 is a perspective diagram which shows a configuration of a mobile phone (also including a PHS) which is an example of the electronic equipment of the invention.

FIG. 12 is a perspective diagram which shows a configuration of a digital still camera which is an example of the electronic equipment of the invention.

FIGS. 13A to 13D are graphs which show various characteristics of the light emitting elements (in a case of using a green light emitting material as an indicator material) according to an example of the invention.

FIGS. 14A to 14D are graphs which show various characteristics of the light emitting elements (in a case of using a red light emitting material as an indicator material) according to an example of the invention.

### DESCRIPTION OF EXEMPLARY EMBODIMENTS

Below, description will be given of a film-forming ink, a discharge inspection method, a discharge inspection apparatus, a method for manufacturing a light emitting element, a light emitting element, a light emitting apparatus, and electronic equipment of the invention based on favorable embodiments shown in the drawings. Here, the scale of each of the sections in each of the diagrams is changed as appropriate for convenience of description and the configurations in the diagrams do not necessarily match the actual scale.

### Film-Forming Ink

First, simple description will be given of the film-forming ink of the invention.

The film-forming ink of the invention is an ink for forming a hole transport layer or a hole injection layer, which is included in an organic electroluminescent element, using a liquid phase process.

The film-forming ink of the invention includes a film-forming material which is a material which configures a hole transport layer or a hole injection layer, or a precursor thereof, and a liquid medium for dispersing or dissolving the film-forming material, in which an indicator material which emits light by being irradiated with excitation light is added to the film-forming material. Due to this, since the indicator material emits light by being irradiated with excitation light, it is possible to measure the light emitting state and to recognize the coated state of the film-forming ink with high precision based on the measuring results. Accordingly, it is possible to perform inspection (discharge inspection) of the liquid droplet discharging head with high precision even when the film-forming ink is not colored with a high concentration.

Here, in general, the film-forming ink used when forming a hole transport layer or a hole injection layer using a liquid phase process generally has an extremely low concentration of the film-forming material and has hardly any color. Therefore, even when simply observing the coated film-forming ink, it is difficult to measure (recognize) the coating state thereof (in particular, a boundary section between a coating region and a non-coated region). In addition, high functional ink has a high wetting and spreading property onto a substrate (a discharge target) and for this reason the boundary (outline section) is blurred and measurement (recognition) is difficult after all. Moreover, in recent years, as the definition of displays has become higher, the definition of the nozzles of the liquid droplet discharging head used in the liquid phase process has also increased, and thus the discharge amount of the liquid droplets discharged at one time is extremely small and it is more and more difficult to measure the coating state. Accordingly, by applying the invention to the film-forming ink, the effect thereof is remarkable.

Below, detailed description will be given of each of the components of the film-forming ink of the invention.

### Film-Forming Material

The film-forming material which is included in the film-forming ink of the invention is a constituent material of a film for the purpose of forming a film, or a precursor thereof, that is, a material which configures a hole transport layer or a hole injection layer, or a precursor thereof. Note that detailed description will be given below of these materials. In addition, the “hole transport layer” and the “hole injection layer” used in the forming of the film-forming ink of the invention include not only those layers commonly referred to as a hole transport layer or a hole injection layer, but also any type of organic layer (for example, an intermediate layer or the like) which is arranged between an anode and a light emitting layer and which is able to be formed using a liquid phase process.

In addition, as the film-forming material, for example, two or more types of components may be used in combination.

In a case in which the film-forming material has an organic material as the main material, it is possible to dissolve the film-forming material in a liquid medium by selecting the liquid medium as appropriate. On the other hand, in a case in which the film-forming material includes an inorganic material, or a case in which the film-forming material is an organic material but is insoluble in a liquid medium, the film-forming material may be dispersed in a liquid medium.

The content of the film-forming material in the film-forming ink is not particularly limited; however, for example, 0.01 wt % to 10 wt % is preferable, 0.05 wt % to 5 wt % is more preferable, and 0.1 wt % to 3 wt % is even more preferable. Due to this, it is possible for the discharge property from the liquid droplet discharging head (an ink jet head) for forming the film to be particularly excellent. In addition, the wetting property of the film-forming ink with respect to the coating target is excellent and, as a result, it is possible for the film-forming property of the film-forming ink to be excellent.

### Indicator Material

The indicator material which is added to the film-forming material described above emits light by being irradiated with excitation light.

As the indicator material, it is possible to use the same material as the light emitting material which is included in the light emitting layer of the light emitting element to be described below, that is, a fluorescent material or a phosphorescent material.

In detail, examples of the phosphorescent material to be used as the indicator material include Ir(ppy)₂(Fac-tris(2-phenypyridine)iridium), Ppy₂Ir(acac)(Bis(2-phenyl-pyridinato-N,C2)iridium(acetylacetone), Bt₂Ir(acac)(Bis(2-phenylbenxothiozolato-N,C2′)iridium(III)(acetylacetonate)), Btp₂Ir(acac)(Bis(2-2′-benzothienyl)-pyridinato-N,C3)Iridium (acetylacetonate), FIrpic(Iridium-bis(4,6difluorophenyl-pyridinato-N,C2)-picolinate), Ir(pmb)₃(Iridium-tris(1-phenyl-3-methylbenzimidazolin-2-ylidene-C,C(2)′), FIrN₄(((Iridium(III)bis(4,6-difluorophenylpyridinato)(5-(pyridin-2-yl)-tetrazolate), Firtaz ((Iridium(III)bis(4,6-difluorophenylpyridinato)(5-(pyridine-2-yl)-1,2,4-triazolate), PtOEP (2,3,7,8,12,13,17,18-Octaethyl-21H,23H-porphine, platinum (II)), and the like.

Examples of the fluorescent material used as the indicator material include Alq₃(8-hydroxyquinolinato)aluminum, rubrene, perylene, 9,10-diphenylanthracene, tetraphenylbutadiene, Nile red, coumarin 6, quinacridone, and the like.

In addition to the above, it is possible to use the light emitting material (the phosphorescent material or the fluorescent material) which is included in the light emitting layer of the light emitting element to be described below as the indicator material. In addition, the indicator material may be configured by one type of phosphorescent material or fluorescent material, or may be configured by combining two or more types of phosphorescent material or fluorescent material.

In addition, when the hole transport layer or the hole injection layer is formed using the film-forming ink, it is preferable that the light emitting function of the indicator material be eliminated or reduced in the film-forming process. Due to this, when manufacturing the light emitting element using the hole transport layer or the hole injection layer formed using the film-forming ink, it is possible to prevent the indicator material having an adverse influence on characteristics of the light emitting element.

For example, it is preferable that the light emitting function of the indicator material be eliminated or reduced by being heated. When forming the hole transport layer or the hole injection layer using the liquid phase process, in general, a heating treatment (firing) is performed with respect to the coated film-forming ink. Accordingly, it is possible to eliminate or reduce the light emitting function of the indicator material using the heat of the heating treatment.

From this point of view, it is preferable that the temperature of the heating treatment described above be the temperature at which the light emitting function of the indicator material is eliminated or reduced or higher. In other words, it is preferable that the heating treatment described above be able to eliminate or reduce the light emitting function of the indicator material while preserving the functions of the hole transport layer or the hole injection layer, that is, the hole transporting property or the hole injection property to the necessary extent.

In addition, in a case in which the light emitting function is eliminated or reduced, depending on the material or the like with the light emitting function, and the treatment temperature or the treatment time conditions may be appropriately selected such as shortening the treatment time at a high temperature or lengthening the treatment time at a low temperature.

In addition, it is preferable that the excitation light which excites the indicator material be ultraviolet light. Due to this, it is possible to efficiently excite the indicator material.

In addition, it is preferable that the light emitted from the indicator material be visible light or infrared light. Due to this, it is possible to efficiently measure the light emitting state of the indicator material. In particular, in a case in which the excitation light is ultraviolet light, since the light emitting wavelength of the indicator material and the wavelength of the excitation light are different, it is possible to efficiently measure the light emitting state of the indicator material.

In addition, it is preferable to use a phosphorescent material as the indicator material. Due to this, even when the irradiation of the excitation light is stopped, it is possible to measure the light emitting state of the indicator material. Therefore, it is possible to measure the light emitting state of the indicator material with high precision while simplifying the configuration of the discharge inspection apparatus.

The added amount of the indicator material with respect to the film-forming material is not particularly limited; however, for example, 0.01 wt % to 10 wt % is preferable, and 0.1 wt % to 5 wt % is more preferable. Due to this, it is possible for the light emitted from the indicator material in the discharge inspection to be excellent while preventing the indicator material having an adverse influence with respect to the obtained hole transport layer or hole injection layer.

### Liquid Medium

The liquid medium which is included in the film-forming ink of the invention dissolves or disperses the film-forming material described above, that is, the liquid is a solvent or a dispersion medium. The majority of the liquid medium is removed in the film-forming process to be described below. Here, in a state in which the film-forming material is dissolved or dispersed in the liquid medium, the indicator material described above may be dispersed alone in the liquid medium, or may be dissolved or dispersed along with the film-forming material in the liquid medium.

As such a liquid medium, the optimum medium is selected and used according to the type or the like of the film-forming material and, although not particularly limited, examples thereof include 1-propyl-4-phenyl benzene (boiling point 280° C.), N-methyldiphenylamine (boiling point 296 to 297° C.), dibenzyl ether (boiling point 295° C.), 4,4′-difluorodiphenylmethane (boiling point 258° C.), α,α-dichlorodiphenylmethane (boiling point 305° C.), 2-phenoxytoluene (boiling point 265° C.), dimethyl benzyl ether (boiling point 270° C.), 2-phenoxy 1,4-dimethyl benzene (boiling point 280° C.), 2,3,5-tri-methy diphenyl ether (boiling point 295° C.), 2,2,5-tri-methy diphenyl ether (boiling point 290° C.), 3-phenoxytoluene (boiling point 271 to 273° C.), 2-phenoxytetrahydropuran (boiling point 274.7° C.), 4-(3-phenylpropyl)pyridine (boiling point 322° C.), 2-phenylpyridine (boiling point 268° C.), 3-phenylpyridine (boiling point 272° C.), benzyl benzoate (boiling point 324° C.), 2-phenylanisole (boiling point 274° C.), ethyl 2-naphthyl ether (boiling point 282° C.), 1,1-bis(3,4-dimethylphenyl) ethane (boiling point 333° C.), 4-methoxybenzaldehyde dimethyl acetal (boiling point 253° C.), 1,3-dipropoxybenzene (boiling point 251° C.), 1,2-dimethoxy-4-(1-propenyl)benzene (boiling point 264° C.), diphenyl ether (boiling point 259° C.), diphenyl methane (boiling point 265° C.), 4-isopropylbiphenyl (boiling point 298° C.), diethyleneglycol butylmethyl ether (boiling point 212° C.), triethyleneglycol butylmethyl ether (boiling point 261° C.), diethyleneglycol dibutyl ether (boiling point 256° C.), triethyleneglycol dimethyl ether (boiling point 216° C.), diethyleneglycol monobutyl ether (boiling point 230° C.), tripropyleneglycol dimethyl ether (boiling point 215° C.), tetraethyleneglycol dimethyl ether (boiling point 275° C.) and the like, and it is possible to use at least one out of these alone or to use two or more in a mixture.

In addition, it is preferable to use a liquid medium with as little antagonism as possible with respect to the film-forming material which is included in the film-forming ink or to the other components.

In addition, in a case in which there is a possibility that the liquid medium will remain in the film after the film forming, it is preferable to use a liquid medium which inhibits as little as possible the characteristics according to the purpose of the film. For example, it is preferable to select each of the components of the liquid medium in consideration of the electrical characteristics.

The film-forming ink as described above is used in film forming according to a liquid phase process using a liquid droplet discharging apparatus.

### Liquid Droplet Discharging Apparatus

Next, brief description will be given of the overall configuration of the liquid droplet discharging apparatus which is provided with the discharge inspection apparatus of the invention.

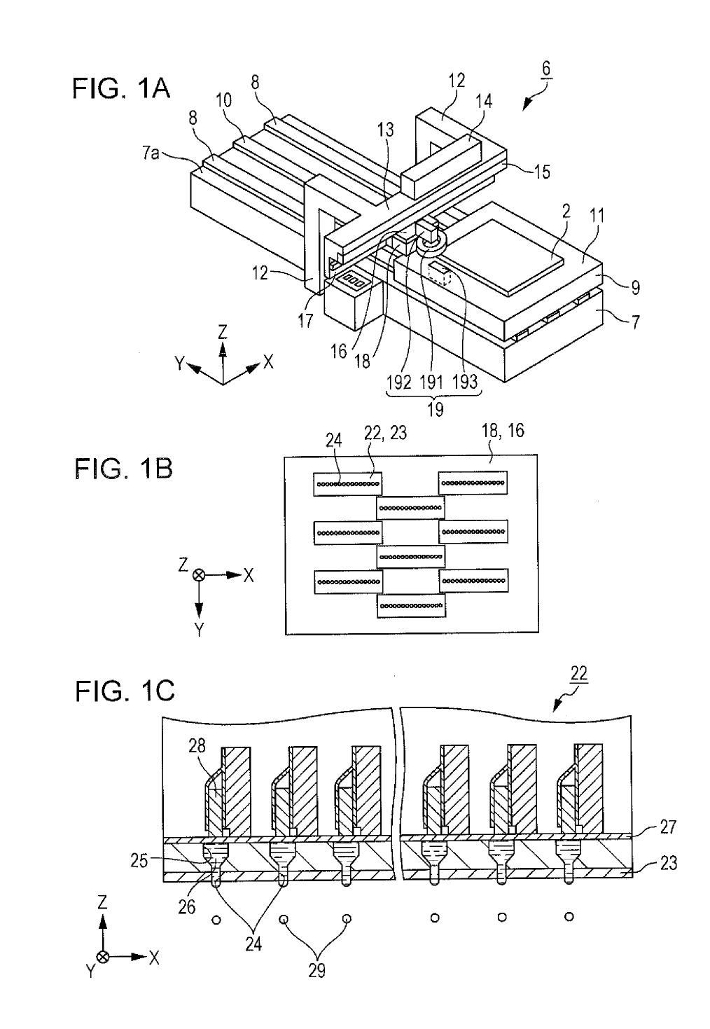

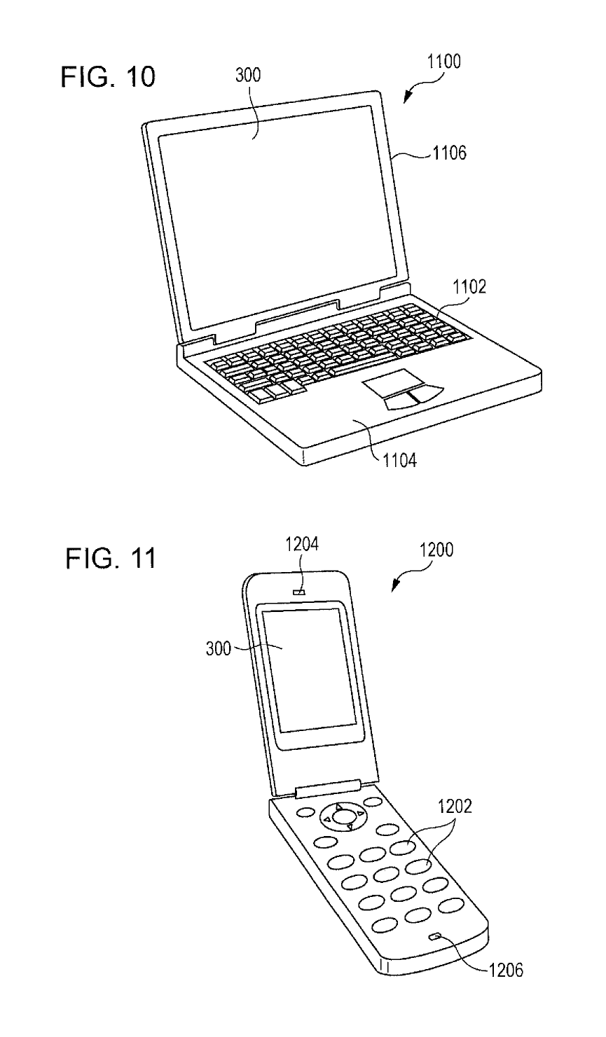

FIG. 1A is a perspective diagram which shows a schematic configuration of the liquid droplet discharging apparatus which is provided with a discharge inspection apparatus according to an embodiment of the invention, FIG. 1B is a schematic planar diagram which shows an arrangement of liquid droplet discharging heads, and FIG. 10 is a cross-sectional diagram which shows a schematic configuration of a main section of the liquid droplet discharging head. Here, for convenience of explanation, FIGS. 1A to 1C show the X axis, the Y axis, and the Z axis which are orthogonal to each other. In addition, the direction which is parallel to the X axis is referred to as the “X axis direction”, the direction which is parallel to the Y axis is referred to as the “Y axis direction”, and the direction which is parallel to the Z axis is referred to as the “Z axis direction”. In addition, in FIGS. 1A to 1C, the Z axis is along the vertical direction and the +Z axis direction side (the leading end side of the arrow showing the Z axis) is referred to as “up” and the −Z axis direction side (the base end side of the arrow showing the Z axis) is referred to as “down”.

A liquid droplet discharging apparatus 6 shown in FIGS. 1A to 1C is an ink jet apparatus. The liquid droplet discharging apparatus 6 is provided with a base 7, a pair of guiding rails 8, a stage 9, a main scanning position detection apparatus 10, a support base 12, a guiding member 13, a storage tank 14, a guide rail 15, a carriage 16, a sub-scanning position detection apparatus 17, a head unit 18, and a discharge inspection apparatus 19.

The base 7 has a rectangular shape which has an upper surface 7a along the X axis direction and the Y axis direction. Then, the pair of guiding rails 8, which extend along the Y axis direction, is installed on the upper surface 7a of the base 7.

The stage 9 is attached to the pair of guide rails 8 via a linear motion mechanism which is not shown in the diagram. Due to this, by moving the stage 9 along the pair of guiding rails 8, it is possible to relatively move the liquid droplet discharging head 22 to be described below in the main scanning direction (the Y axis direction in the present embodiment) with respect to the stage 9. In the present embodiment, for example, a linear motor is used as such a linear motion mechanism and the forward movement and backward movement of the stage 9 are repeated at a predetermined speed along the Y axis direction. Here, the linear motion mechanism is not limited to a linear motor and, for example, may be a screw type linear motion mechanism, or the like.

In addition, the main scanning position detection apparatus 10 is provided on the upper surface 7a of the base 7. The position (that is, the position in the main scanning direction) of the stage 9 in the Y axis direction with respect to the base 7 is detected by the main scanning position detection apparatus 10.

A mounting surface 11 on which a recording medium 2 is mounted is formed on the upper surface of the stage 9. A suction type chuck mechanism which is not shown in the diagram is provided on the mounting surface 11. The recording medium 2 on the mounting surface 11 is adsorbed and fixed with respect to the mounting surface 11 by the chuck mechanism.

In addition, the pair of support bases 12 which extend to the upper side is provided at both end sections of the base 7 in the X axis direction. The guiding member 13 which extends along the X axis direction is provided on the pair of support bases 12. The storage tank 14 in which a film-forming ink 26 is stored is installed on the upper side of the guiding member 13.

On the other hand, the guiding rail 15 which extends along the X axis direction is installed on the lower side of the guiding member 13. The carriage 16 is attached to the guiding rail 15 via a linear motion mechanism which is not shown in the diagram. Due to this, by moving the carriage 16 along the guiding rail 15, it is possible to relatively move the liquid droplet discharging head 22 to be described below in the sub-scanning direction (the X axis direction in the present embodiment) with respect to the stage 9. In the present embodiment, for example, a linear motor is used as such a linear motion mechanism and the carriage 16 is moved along the X axis direction at an arbitrary timing (for example, when switching the forward motion and the backward motion of the main scanning described above). Here, the linear motion mechanism is not limited to a linear motor and, for example, may be a screw type linear motion mechanism, or the like.

In addition, the sub-scanning position detection apparatus 17 is provided on the carriage 16 side of the guiding member 13. The position (that is, the position in the sub-scanning direction) of the carriage 16 in the X axis direction with respect to the guiding member 13 is detected by the sub-scanning position detection apparatus 17.

The head unit 18 is installed in the carriage 16. As shown in FIG. 1B, the head unit 18 is provided with a plurality (six in the present embodiment) of liquid droplet discharging heads 22. Each of the liquid droplet discharging heads 22 is provided with a nozzle plate 23 and a plurality of discharge nozzles 24 are formed in the nozzle plates 23. Here, the number, arrangement, and the like of the liquid droplet discharging heads 22 and the discharge nozzles 24 are not limited to those illustrated.

To be more specific, each of the liquid droplet discharging heads 22 has the nozzle plate 23, a cavity 25, a vibration plate 27, and a piezoelectric element 28.

A plurality of discharge nozzles 24 are formed on the nozzle plate 23 to line up in the X axis direction. The cavities 25 (pressure chambers) which communicate with the discharge nozzles 24 are provided on the upper side with respect to the nozzle plate 23 to correspond to each of the discharge nozzles 24. The cavities 25 communicate with the storage tank 14 described above via a flow path which is not shown in the diagram and the film-forming ink 26 is supplied from the storage tank 14.

In addition, the vibration plate 27 is arranged on the upper side of the cavity 25. The vibration plate 27 configures a portion of the inner wall surface of the cavity 25. The piezoelectric element 28 is arranged on the surface of the opposite side to the cavity 25 of the vibration plate 27. The piezoelectric element 28 vibrates the vibration plate 27 in the up and down direction (the Z axis direction) by expanding or contracting in the up and down direction (the Z axis direction) upon receiving an element driving signal. Due to this, the inside of the cavity 25 is pressurized along with a reduction in the volume inside the cavity 25. As a result, the film-forming ink 26 is discharged as liquid droplets 29 from the discharge nozzles 24 in amounts which correspond to the contraction amount of the volume inside the cavity 25. Liquid droplets 29 which are discharged land on the recording medium 2.

The discharge inspection apparatus 19 measures landing information such as the landing position or the landing surface area of the liquid droplets 29 on the recording medium 2 and performs inspection of the liquid droplet discharging head 22 based on the measuring results.

### Discharge Inspection Apparatus

Below, description will be given of the configuration of the discharge inspection apparatus 19.

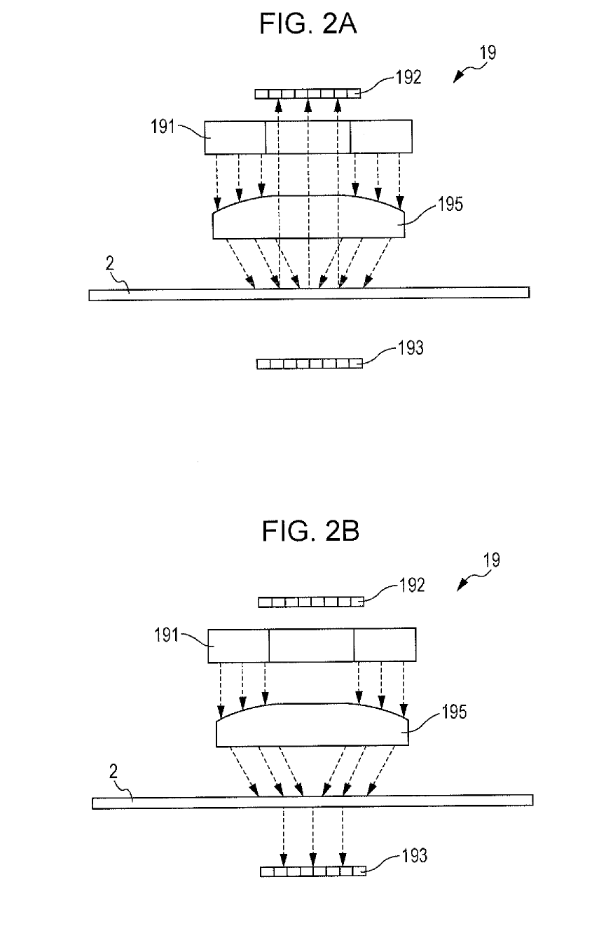

FIGS. 2A and 2B are diagrams which schematically show a schematic configuration of the discharge inspection apparatus which is provided in the liquid droplet discharging apparatus shown in FIGS. 1A to 1C.

The discharge inspection apparatus 19 shown in FIGS. 2A and 2B performs inspection of the liquid droplet discharging head 22 which discharges the film-forming ink as liquid droplets 29 on the recording medium 2. As shown in FIGS. 2A and 2B, the discharge inspection apparatus 19 has a light emitting section 191 (a light source) which emits light which is irradiated onto the recording medium 2, measuring sections 192 and 193 (imaging sections) which measure the light from the recording medium 2, and an optical system 195 which is arranged between the light emitting section 191 and the measuring section 192, and the recording medium 2.

In the present embodiment, the light emitting section 191 and the measuring section 192 are attached to the carriage 16 described above, while the measuring section 193 is embedded in the stage 9 described above (refer to FIG. 1A). In addition, although not shown, the optical system 195 is also attached to the carriage 16. Here, the light emitting section 191, the measuring sections 192 and 193, and the optical system 195 need not be assembled with the liquid droplet discharging apparatus 6 and, for example, the light emitting section 191, the measuring sections 192 and 193, and the optical system 195 may be set as a separate unit from the liquid droplet discharging apparatus 6.

The light emitting section 191 emits light which includes excitation light which excites the indicator material which is included in the film-forming ink on the recording medium 2. The light which is emitted from the light emitting section 191 may be a single wavelength or may have a width in a predetermined wavelength band; however, it is preferable that the emitted light wavelength of the indicator material, that is, the wavelength of the light which is measured by the measuring sections 192 and 193, be different. Due to this, with a comparatively simple configuration, it is possible to prevent or reduce the measuring of the light from the light emitting section 191 in the measuring sections 192 and 193 and to efficiently measure the light emitted from the indicator material in the measuring section 192 or 193. Here, the light emitted from the light emitting section 191 may include the light emitting wavelength of the indicator material and, in such a case, an optical filter may be installed as appropriate according to necessity.

In addition, the light emitting section 191 is not particularly limited; however, for example, it is possible to use a light emitting diode (LED) light source, a laser light source, a halogen light source, or the like.

In the present embodiment, the light emitting section 191 forms a ring. Then, the optical system 195 is a condenser lens which has a function of condensing the light from the light emitting section 191 on a predetermined region of the recording medium 2 (a region where a test pattern to be described below is formed). In addition, the optical system 195 has a function of transmitting light from the recording medium 2. Here, the shape of the light emitting section 191 is arbitrary without being particularly limited. In addition, the optical system 195 is appropriately designed according to the configuration or the like of the light emitting section 191 or the measuring section 192, and may be omitted according to the configuration or the like of the light emitting section 191 and the measuring section 192, or may have various types of optical elements other than a condensing lens, for example, an optical filter.

The measuring sections 192 and 193 measure the light from the recording medium 2, more specifically, the light emitted from the indicator material which is included in the film-forming ink on the recording medium 2. Here, the measuring section 192 is arranged on the same side as the light emitting section 191 with respect to the recording medium 2. In addition, the measuring section 192 is arranged on the opposite side to the recording medium 2 with respect to the light emitting section 191. Then, the measuring section 192 measures the light emitted from the indicator material through the inner side of the ring-shaped light emitting section 191. On the other hand, the measuring section 193 is arranged on the opposite side to the light emitting section 191 with respect to the recording medium 2. Then, the measuring section 193 measures the light emitted from the indicator material via the recording medium 2.

In addition, the measuring sections 192 and 193 are not particularly limited as long as it is possible for each to measure the light emitted from the indicator material; however, for example, it is possible to use an imaging element such as a Charge Coupled Device (CCD), or a Complementary Metal Oxide Semiconductor (CMOS). By using such an imaging element as the measuring sections 192 and 193, it is possible to recognize regions where the light emitted from the indicator material is excited and regions where the light is not excited on the recording medium 2, and, as a result, it is possible to recognize the coating region of the film-forming ink on the recording medium 2.

When the light emitted from the indicator material on the recording medium 2 is measured, it is sufficient to use at least one of the measuring sections 192 and 193; however, it is possible to perform the measurement by appropriately selecting any one out of the measuring sections 192 and 193 according to the type or the like of the indicator material or the recording medium 2. For example, in a case in which the recording medium 2 has transmissivity with respect to the emitted light wavelength of the indicator material, either of the measuring sections 192 and 193 may be used in the measurement; however, in a case in which the recording medium 2 has high reflectivity with respect to the excitation light, measurement is performed using the measuring section 193. In addition, in a case in which the recording medium 2 does not have transmissivity with respect to the emitted light wavelength of the indicator material, the measurement is performed using the measuring section 192. Here, in the present embodiment, description was given of an example of a case in which the discharge inspection apparatus 19 is provided with two of the measuring sections 192 and 193; however, depending on the type or the like of the indicator material or the recording medium 2, either of the measuring sections 192 and 193 may be omitted.

According to the discharge inspection apparatus 19 described above, since the indicator material on the recording medium 2 emits light by being irradiated with excitation light, it is possible to measure the light emitting state and to recognize the coated state of the film-forming ink with high precision based on the measuring results. Accordingly, it is possible to perform inspection (discharge inspection) of the liquid droplet discharging head 22 with high precision even when the film-forming ink is not colored with a high concentration.

Here, in the discharge inspection apparatus 19, there is a concern that the measurement precision in the measuring sections 192 and 193 will decrease due to light from the light emitting section 191 being incident to the measuring section 192 by being reflected by the recording medium 2 or the light from the light emitting section 191 being incident to the measuring section 193 by passing through the recording medium 2. Accordingly, to improve the measurement precision, it is preferable that the measuring sensitivity of the measuring sections 192 and 193 be lowered in the wavelength bands other than the wavelength band of the light emitted from the indicator material, or that optical filters be provided between the measuring sections 192 and 193 and the recording medium 2. In addition, as in the following modification examples, the light emitting section 191 may be arranged such that the light from the light emitting section 191 is not incident to the measuring sections 192 and 193.

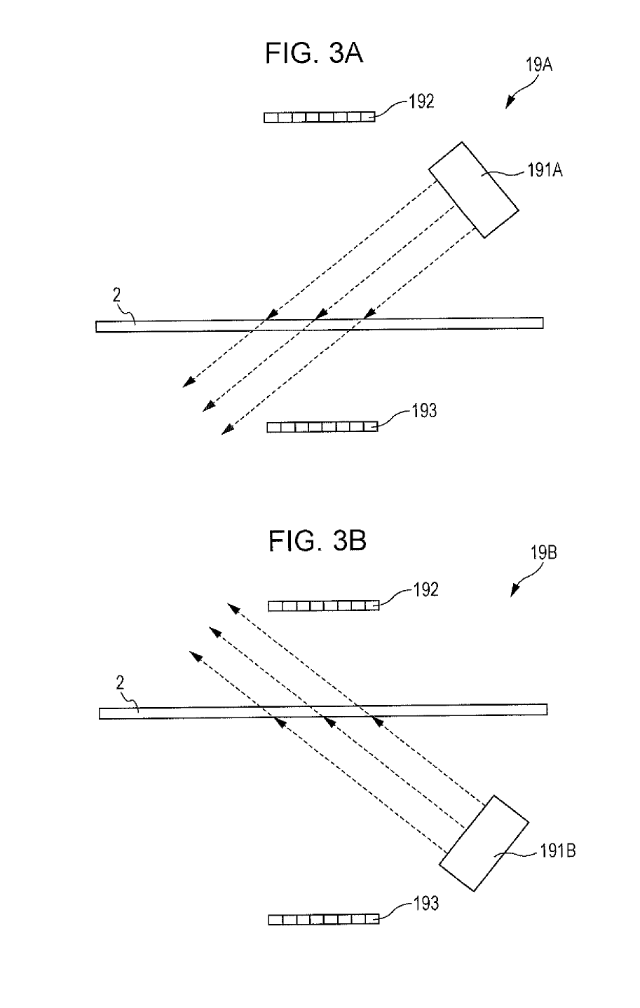

FIGS. 3A and 3B are diagrams which schematically show a schematic configuration of a modification example of the discharge inspection apparatus which is provided with the liquid droplet discharging apparatus shown in FIGS. 1A to 1C.

A discharge inspection apparatus 19A according to the modification example shown in FIG. 3A is provided with a light emitting section 191A instead of the light emitting section 191 which omits the optical system 195 in the discharge inspection apparatus 19 described above and is in other respects the same as the discharge inspection apparatus 19.

The light emitting section 191A is arranged so as to emit and irradiate light with respect to the recording medium 2 from an inclined direction. Due to this, even without using an optical filter or the like, it is possible to prevent or suppress light from the light emitting section 191A from being incident to the measuring sections 192 and 193. In addition, the light emitting section 191A is arranged on the upper side with respect to the recording medium 2. Due to this, even in a case in which the recording medium 2 does not have transmissivity with respect to the excitation light, it is possible to irradiate the excitation light with respect to the film-forming ink on the recording medium 2.

A discharge inspection apparatus 19B according to a modification example shown in FIG. 3B is provided with a light emitting section 191B instead of the light emitting section 191 which omits the optical system 195 in the discharge inspection apparatus 19 described above and is in other respects the same as the discharge inspection apparatus 19.

The light emitting section 191B is arranged so as to emit and irradiate light with respect to the recording medium 2 from an inclined direction. Due to this, even without using an optical filter or the like, it is possible to prevent or suppress light from the light emitting section 191B from being incident to the measuring sections 192 and 193. In addition, the light emitting section 191B is arranged on the lower side with respect to the recording medium 2. Due to this, in a case in which the recording medium 2 has transmissivity with respect to excitation light, it is possible to irradiate the excitation light with respect to the film-forming ink on the recording medium 2 via the recording medium 2 from below.

Above, description was given of the configuration of the discharge inspection apparatus 19; however, the discharge inspection method in which the discharge inspection apparatus 19 is used will be described in detail below.

### Control System of Liquid Droplet Discharging Apparatus

Next, description will be given of the control system of the liquid droplet discharging apparatus 6 which includes the discharge inspection apparatus 19.

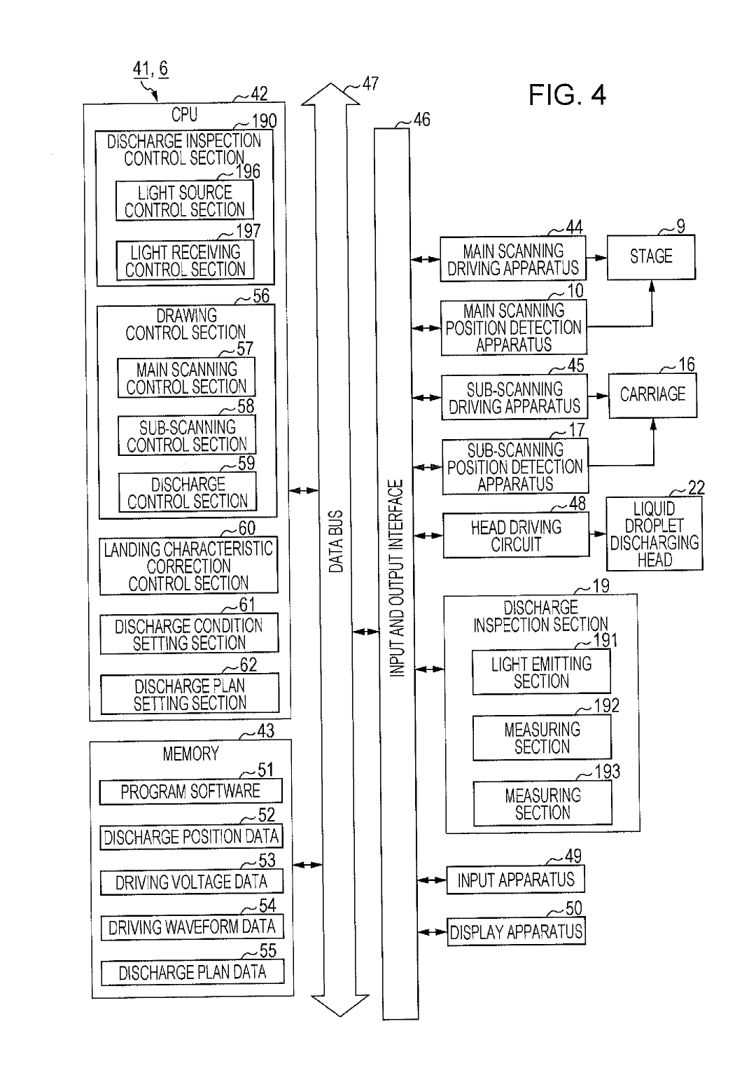

FIG. 4 is a block diagram which shows the control system of the liquid droplet discharging apparatus shown in FIGS. 1A to 1C.

As shown in FIG. 4, the liquid droplet discharging apparatus 6 is provided with a control apparatus 41 (a control section) which controls the operations of each of the sections of the liquid droplet discharging apparatus 6. The control apparatus 41 is provided with a central processing unit (CPU) 42 which performs various types of calculation processes, and a memory 43 (a storage section) which stores various types of information.

Here, in the CPU 42, the main scanning position detection apparatus 10, the sub-scanning position detection apparatus 17, and the discharge inspection apparatus 19 described above are each connected via an input and output interface 46 and a data bus 47. In addition to the above, in the CPU 42, the main scanning driving apparatus 44, a sub-scanning driving apparatus 45, a head driving circuit 48, an input apparatus 49, and a display apparatus 50 are connected with each other via the input and output interface 46 and the data bus 47.

The main scanning driving apparatus 44 is a drive source for moving the stage 9 described above in the main scanning direction and the sub-scanning driving apparatus 45 is a drive source for moving the carriage 16 described above in the sub-scanning direction. In addition, the head driving circuit 48 drives the liquid droplet discharging head 22 described above.

The input apparatus 49 is an apparatus to which various types of operation conditions of the liquid droplet discharging apparatus 6 are input, for example, coordinate information for discharging the liquid droplets 29 onto the recording medium 2 is input from an external apparatus which is not shown in the diagram. In addition, the display apparatus 50 is an apparatus which displays various types of information such as the processing conditions and the operation progress for the liquid droplet discharging apparatus 6. It is possible for an operator to perform the operations using the input apparatus 49 based on the information which is displayed on the display apparatus 50.

The memory 43 is configured to have, for example, a semiconductor memory such as a RAM or a ROM, an external storage apparatus such as a hard disk or a DVD-ROM, or the like. The memory 43 stores various types of information necessary for the operation of the CPU 42.

To be specific, a storage region which stores a program software 51 in which the control procedure for the operations in the liquid droplet discharging apparatus 6 is recorded is set in the memory 43. In addition, a storage region for storing discharge position data 52 which is coordinate data of the discharge positions for discharging onto the recording medium 2 is also set in the memory 43.

Moreover, a storage region for storing a plurality of discharge conditions such as driving voltage data 53, which is data which shows the relationship between the driving waveform and the discharge amount when driving the liquid droplet discharging head 22, and driving waveform data 54 for driving the liquid droplet discharging head 22 is set in the memory 43. In addition, a storage region for storing discharge plan data 55 which is data of driving voltages for each place of discharging is set in the memory 43. Furthermore, a storage region which functions as a work area, a temporary file, or the like for the CPU 42, or various other types of storage regions are set in the memory 43.

The CPU 42 controls each of the sections of the liquid droplet discharging apparatus 6 according to the program software 51 which is stored in the memory 43. The CPU 42 has a drawing control section 56, a discharge inspection control section 190, a landing characteristic correction control section 60, a discharge condition setting section 61, and a discharge plan setting section 62.

The drawing control section 56 performs control for drawing by discharging the liquid droplets 29 from the liquid droplet discharging head 22. The drawing control section 56 has a main scanning control section 57 which drives and controls the main scanning driving apparatus 44, a sub-scanning control section 58 which drives and controls the sub-scanning driving apparatus 45, and a discharge control section 59 which drives and controls the head driving circuit 48. The main scanning control section 57 performs control for moving the stage 9 in the main scanning direction at a predetermined speed. The sub-scanning control section 58 performs control for moving the liquid droplet discharging head 22 in the sub-scanning direction by a predetermined sub-scanning amount. The discharge control section 59 controls the discharge amounts and whether or not there is discharging for each of a plurality of nozzles belonging to the liquid droplet discharging head 22.

The discharge inspection control section 190 performs control for executing discharge inspection of the liquid droplet discharging head 22 using the discharge inspection apparatus 19. The discharge inspection control section 190 has a light source control section 196 which controls the light emitting section 191, and a light receiving control section 197 which controls the measuring sections 192 and 193.

The landing characteristic correction control section 60 acquires correction values based on the amount of shifting between inspection results of the discharge inspection apparatus 19 (landing information such as the landing position or the landing area of the test pattern) and correct landing information set in advance, and corrects the landing position of the liquid droplets 29 which are discharged by the liquid droplet discharging head 22 on the recording medium 2 by carrying out feedback to the drawing control section 56. The discharge condition setting section 61 sets the discharge amount and the number of discharges of the liquid droplets 29 to be discharged from the discharge nozzles 24 based on the amount and the discharge characteristics of the film-forming ink 26 to be discharged onto the coating region. The discharge plan setting section 62 sets a driving waveform of the piezoelectric element 28 in each of the places for discharging the liquid droplets 29.

### Discharge Inspection Method

Next, as an example of the discharge inspection method of the invention, description will be given of the discharge inspection method using the discharge inspection apparatus 19 described above.

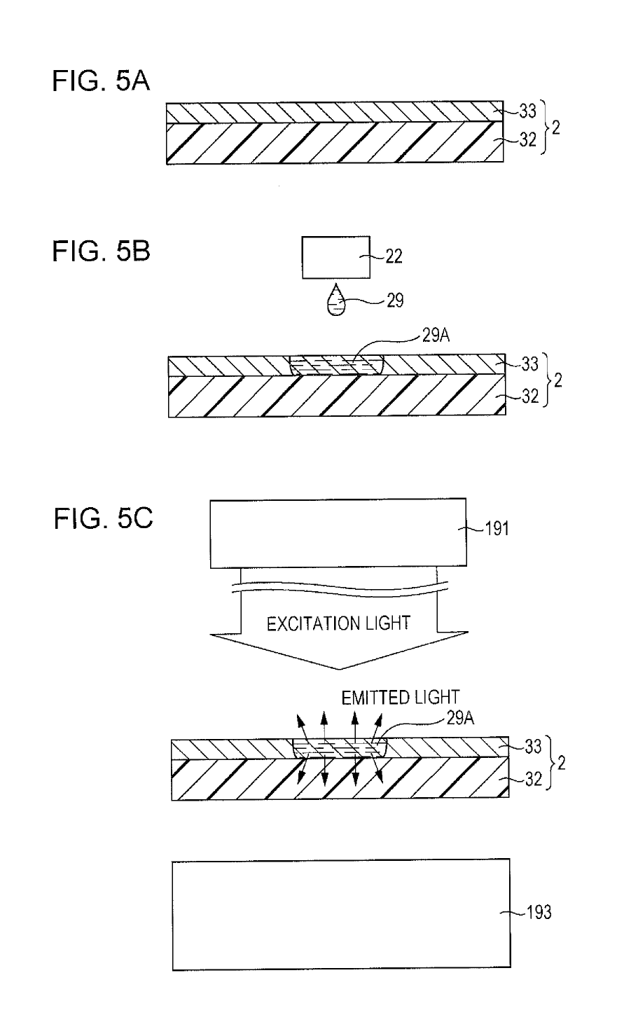

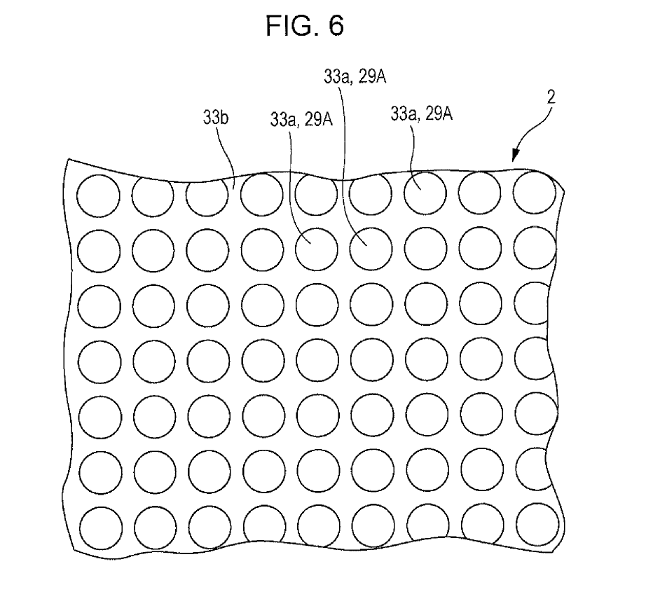

FIGS. 5A to 5C are diagrams which illustrate a discharge inspection method (an example of the discharge inspection method of the invention) using the discharge inspection apparatus shown in FIGS. 2A and 2B. In addition, FIG. 6 is a planar diagram which shows an example of a test pattern in the discharge inspection method shown in FIGS. 5A to 5C.

The discharge inspection method using the discharge inspection apparatus 19 has [A] a step of discharging the film-forming ink described above as liquid droplets 29 using the liquid droplet discharging head 22 to coat the recording medium 2, and [B] a step of irradiating the film-forming ink (dots 29A) on the recording medium 2 with excitation light and measuring the light emitting state of the indicator material, and performs inspection of the liquid droplet discharging head 22 based on the measuring results in step [B].

Below, detailed description will be given in sequence of each of the steps of the discharge inspection method.

### A

### —A1—

First, as shown in FIG. 5A, the recording medium 2 is prepared.

The recording medium 2 is a recording medium for discharge inspection. The recording medium 2 has a base material 32, and an ink absorbing layer 33 which is laminated on the base material 32.

The base material 32 (the support layer) has the form of a sheet and it is possible for the constituent material of the base material 32 to be appropriately selected depending on whether the measuring section 192 is used or the measuring section 193 is used in the measuring of step [B]. Here, whether the measuring section 192 is used or the measuring section 193 is used in step [B] may be selected and determined according to the constituent material of the base material 32.

The specific constituent material of the base material 32 is not particularly limited; however, for example, it is possible to use a resin material such as polyethylene terephthalate (PET) resin.

In addition, the thickness of the base material 32 is not particularly limited; however, for example, the thickness may be set to approximately several μm to several mm.

The ink absorbing layer 33 (receiving layer) is configured to include, for example, inorganic fine particles such as silica or alumina, and a binder formed of a resin material such as polyvinyl alcohol (PVA). The thickness of the ink absorbing layer 33 is not particularly limited; however, the thickness may be set to approximately several μm to several hundred μm.

By providing the ink absorbing layer 33, it is possible to stabilize the wetting and spreading of the film-forming ink which is coated on the recording medium 2.

In a case in which the discharge inspection apparatus 19 with the configuration shown in FIGS. 2A and 2B is used (the same applies to a case in which the discharge inspection apparatus 19A with the configuration shown in FIG. 3A is used), the recording medium 2 may have transmissivity with respect to the excitation light from the light emitting section 191 or may not have a transmissivity with respect to the excitation light from the light emitting section 191. In a case in which the recording medium 2 (in particular, the base material 32) has transmissivity with respect to the excitation light from the light emitting section 191, for example, it is possible to irradiate the film-forming ink on the recording medium 2 with the excitation light via the recording medium 2 using the discharge inspection apparatus 19B with the configuration shown in FIG. 3B.

In addition, it is preferable that the recording medium 2 have an anti-reflection property with respect to the excitation light, for example, it is preferable that the ink absorbing layer 33 configure a reflection prevention layer. Due to this, in step [B], in a case in which the measuring is performed using the measuring section 192, it is possible to prevent or reduce the excitation light being incident on the measuring section 192.

In addition, it is preferable that the recording medium 2 not emit light due to the excitation light, or that the recording medium 2 emit light at a wavelength which is different to the indicator material due to the excitation light. More specifically, it is preferable that the recording medium 2 not contain a light emitting material such as the indicator material (a fluorescent material or a phosphorescent material), or that the light emitting wavelength of the recording medium 2 be different to that of the indicator material if such is contained. Due to this, in step [B], it is possible to efficiently measure the light emitting state of the indicator material. Here, in a case in which the recording medium 2 emits light, for example, an optical filter may be appropriately provided such that the light thereof is not incident to the measuring sections 192 and 193.

In addition, from the same point of view, it is preferable that at least one out of the base material 32 of the recording medium 2 and the ink absorbing layer 33 be colored black. Due to this, it is possible to suppress the emitted light from the recording medium 2.

In addition, the recording medium 2 may have transmissivity with respect to the emitted light wavelength of the indicator material, or may not have transmissivity with respect to the emitted light wavelength of indicator material; however, in a case of having transmissivity with respect to the emitted light wavelength of the indicator material, it is possible to efficiently perform measurement using the measuring section 193 in step [B].

### —A2—

Next, as shown in FIG. 5B, the liquid droplets 29 of the film-forming ink from the liquid droplet discharging head 22 are discharged to land on the ink absorbing layer 33 of the recording medium 2. Due to this, dots 29A formed of the film-forming ink are formed on the ink absorbing layer 33. Here, the liquid droplets 29 are discharged from each of the nozzles of the liquid droplet discharging head 22 and a test pattern formed of a plurality of the dots 29A arranged in a matrix form is formed on the recording medium 2 (refer to FIG. 6).

### B

Next, as shown in FIG. 50, excitation light from the light emitting section 191 is irradiated with respect to the dots 29A formed of the film-forming ink on the recording medium 2. Due to this, the indicator material in the dots 29A emits light due to the excitation light. Then, the light emitting state is measured. Here, in FIG. 5C, for convenience of explanation, a case in which measuring is carried out using the measuring section 193 is shown as an example; however, it is also possible to carry out the measuring using the measuring section 192.

Based on the results of the measurement, inspection (discharge inspection) of the liquid droplet discharging head 22 is performed. In detail, information (imaging data for the test pattern) relating to the light emitting state measured by the measuring sections 192 and 193 is sent to an image processing apparatus which is not shown in the diagram. In the image processing apparatus, by performing image processing calculations based on the information relating to the measured light emitting state, the diameter (landing diameter) and the positions (landing positions) of each of the dots 29A on the recording medium 2 are calculated. At this time, depending on whether or not the light emitting intensity is a predetermined threshold or higher, the outer peripheral edges of the dots 29A (the boundary shown in FIG. 6 between a region 33a where the film-forming ink is coated and a region 33b where the film-forming ink is not coated) are determined. That is, a region where the light emitting intensity is a predetermined threshold or higher is determined as the region 33a where the film-forming ink is coated (that is, the dots 29A) while a region where the light emitting intensity is less than the threshold is determined as the region 33b where the film-forming ink is not coated.

Here, in the present embodiment, the measuring is performed using the measuring sections 192 and 193 such as imaging elements; however, in a case in which the diameters of the dots 29A or the intervals between the dots 29A are comparatively large, it is possible to recognize the light emitting state of the dots 29A with the naked eye, and due to this, it is possible to perform the discharge inspection such as the determination of whether or not there are missing dots due to nozzle clogging of the liquid droplet discharging head 22 or the like.

In addition, in the discharge inspection, comparison of the calculated values of the landing information such as the landing diameter (the discharge amount) or the landing position of the film-forming ink (the dots 29A) landed on the recording medium 2 and of each of the desired values set in advance is performed, and in a case in which the difference (the shifting amount) in these values exceeds a permissible range, correction values according to the shifting amounts are acquired by the landing characteristic correction control section 60 and it is possible to correct the discharge characteristics such as the discharge amounts and discharge positions of the liquid droplet discharging head 22 by feeding back these correction values to the drawing control section 56.

According to the discharge inspection method described above, since the indicator material emits light by being irradiated with excitation light, it is possible to measure the light emitting state and to recognize the coated state of the film-forming ink with high precision based on the measuring results. Moreover, it is possible to detect not only the presence or absence of the dots 29A (the presence or absence of missing nozzles), but also to detect discharge information such as the position or area of the dots 29A (the landing position or the landing area). Therefore, it is possible to perform inspection (discharge inspection) of the liquid droplet discharging head 22 with high precision even when the film-forming ink is not colored with a high concentration.

### Film-Forming Method (Method for Manufacturing Light Emitting Element)

Next, description will be given of a film-forming method using the film-forming ink described above, that is, a method for manufacturing a hole transport layer or a hole injection layer.

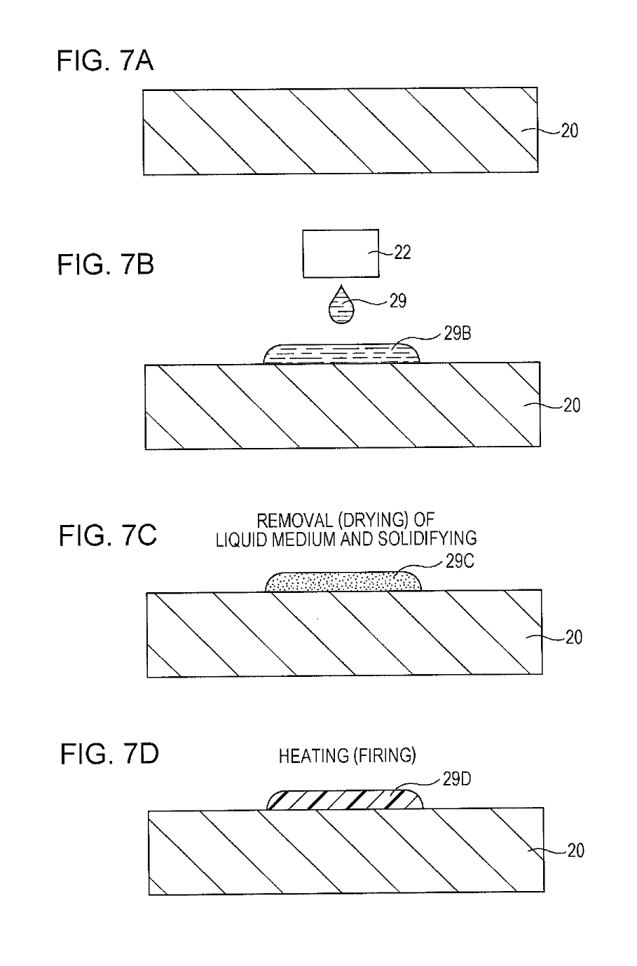

FIGS. 7A to 7D are diagrams which illustrate the film-forming method using the liquid droplet discharging apparatus shown in FIGS. 1A to 1C.

The film-forming method using the film-forming ink of the invention, that is, the method for manufacturing the light emitting element of the invention has [1] a step of coating the film-forming ink described above on a base material (ink imparting step), and [2] a step of forming the hole transport layer or the hole injection layer by curing or solidifying the film-forming ink.

According to the method for manufacturing the light emitting element, as described above, since the film-forming ink for forming the hole transport layer or the hole injection layer includes the indicator material, it is possible to perform inspection of the liquid droplet discharging head, which is used in the coating of the film-forming ink, with high precision. Therefore, it is possible to form the hole transport layer or the hole injection layer with high precision and, as a result, it is possible for the characteristics of the obtained light emitting element to be excellent.

Below, detailed description will be given of each of the steps in sequence.

1
1-1

First, as shown in FIG. 7A, a base material 20 is prepared.

The base material 20 is an object on which the film which is the object of the film-forming is formed. The illustration is given in FIGS. 7A to 7D in a simple manner for convenience of description; however, more specifically, for example, the base material 20 has an anode formed on one surface side of the substrate in a case of forming the hole injection layer, and the base material 20 has an anode formed on one surface side of the substrate or the anode and the hole injection layer are laminated in this order on the one surface side of the substrate in a case of forming the hole transport layer.

1-2

Next, as shown in FIG. 7B, the film-forming ink described above is discharged and supplied as the liquid droplets 29 from the liquid droplet discharging head 22 onto the base material 20. Due to this, a film 29B formed of the film-forming ink is formed on the base material 20. The illustration is given in FIGS. 7A to 7D in a simple manner for convenience of description; however, more specifically, for example, the film 29B is formed on the anode which is formed on the one surface side of the base material 20 in a case of forming the hole injection layer, and the film 29B is formed on the anode or the hole injection layer formed on the one surface side of the base material 20 in a case of forming the hole transport layer.

In addition, the temperature and pressure of the atmosphere in step [1] are each determined according to the composition of the film-forming ink or the boiling point and melting point of the liquid medium and are not particularly limited as long as it is possible to impart the film-forming ink on the base material 20; however, normal temperature and normal pressure are preferable. Accordingly, with normal temperature and normal pressure, it is preferable to use a film-forming ink which is able to be imparted onto the base material 20. Due to this, it is possible to easily perform step [1].

2
2-1

Next, by removing the liquid medium from the film 29B (the film-forming ink) which is formed on the base material 20, as shown in FIG. 7C, the film (a first film) 29C is formed as an intermediate film.

The temperature and pressure of the atmosphere in step [2] are each determined according to the composition of the film-forming ink or the boiling point and melting point of the liquid medium and are not particularly limited; however, the pressure may be atmospheric pressure or may be reduced pressure, and the temperature may be heated or may be the normal temperature.

Here, in this step, it is not necessary to completely remove all of the liquid medium in the film 29C, and the liquid medium of a portion in the film 29C may be left. In addition, it is possible for the liquid medium which is left in the film 29C to be removed by a heating treatment in the subsequent step [3].

2-2

Next, by carrying out a heating treatment (firing) on the film 29C, as shown in FIG. 7D, a film 29D which is the object (that is, the hole transport layer and the hole injection layer) is obtained.

By the heating treatment, the light emitting function of the indicator material in the film 29D is eliminated or reduced. In this manner, when forming the hole transport layer or the hole injection layer, by eliminating or reducing the light emitting function of the indicator material, it is possible to prevent the indicator material from having an adverse influence on the characteristics of the obtained light emitting element. Not only that, but the indicator material with an eliminated or reduced light emitting function exhibits a hole transporting property or a hole injection property, and it is also possible to improve the characteristics of the light emitting element.

This heating treatment is not particularly limited; however, it is possible to perform the heating treatment with a hot plate or infrared rays.

The temperature and time of the heating treatment are determined according to the type or the like of the film-forming material or the indicator material are not particularly limited; however, the heating treatment is performed at a temperature at which it is possible to eliminate or reduce the light emitting function of the indicator material while securing the necessary characteristics in the obtained film 29D, that is, the hole transport property or the hole injection property.

The film 29D obtained in this manner is configured by the film which is the object of the film-forming, that is, the constituent material of the hole transport layer or the hole injection layer or a precursor thereof.

### Display Apparatus

Next, description will be given of a display apparatus which is an example of the light emitting apparatus of the invention.

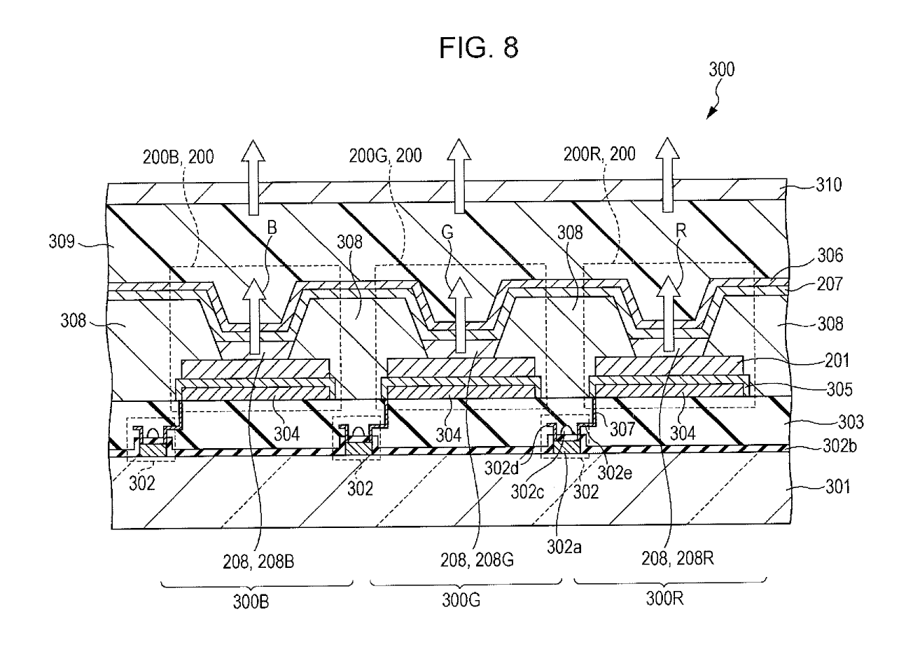

FIG. 8 is a cross-sectional diagram which shows the light emitting apparatus (the display apparatus) according to the embodiment of the invention. Here, below, for convenience of description, the upper side in FIG. 8 is referred to as “up” and the lower side is referred to as “down”.

In a display apparatus 300 shown in FIG. 8, a plurality of light emitting elements 200R, 200G, and 200B are provided to correspond to sub-pixels 300R, 300G, and 300B and a display panel with a top emission structure is configured.

Here, in the present embodiment, description will be given of an example of adopting an active matrix system as the driving system of the display apparatus; however, a passive matrix system may be adopted.

The display apparatus 300 has a substrate 301, a plurality of the light emitting elements 200R, 200G, and 200B, and a plurality of switching elements 302.

The substrate 301 supports the plurality of light emitting elements 200R, 200G, and 200B and a plurality of switching elements 302. Each of the light emitting elements 200R, 200G, and 200B of the present embodiment has a configuration (top emission type) which sends out light from the opposite side to the substrate 301. Accordingly, it is possible to use either of a transparent substrate or an opaque substrate for the substrate 301. Here, in a case in which each of the light emitting elements 200R, 200G, and 200B has a configuration (a bottom emission type) which sends out light from the substrate 301 side, the substrate 301 is set to be substantially transparent (colorless and transparent, colored and transparent, or semi-transparent).

Examples of the constituent material of the substrate 301 include resin materials such as polyethylene terephthalate, polyethylene naphthalate, polypropylene, cycloolefin polymer, polyamide, polyether sulfone, polymethyl methacrylate, polycarbonate, and polyarylate, or glass materials such as quartz glass, and soda glass, and the like, and it is possible to use one type of the above or a combination of two or more types.

Examples of opaque substrates include substrates configured of ceramic material such as alumina, substrates where an oxide film (an insulation film) is formed on a surface of a metal substrates such as stainless steel, substrates configured by a resin material, and the like.

A plurality of switching elements 302 are arranged in a matrix form on the substrate 301.

Each of the switching elements 302 is provided to correspond to each of the light emitting elements 200R, 200G, and 200B and is a driving transistor for driving each of the light emitting elements 200R, 200G, and 200B.

Each of the switching elements 302 has a semiconductor layer 302a formed of silicon, a gate insulation layer 302b which is formed on the semiconductor layer 302a, a gate electrode 302c which is formed on the gate insulation layer 302b, a source electrode 302d, and a drain electrode 302e.

A planarizing layer 303 which is configured by an insulating material is formed so as to cover the plurality of switching elements 302.

The light emitting elements 200R, 200G, and 200B are provided to correspond to each of the switching elements 302 on the planarizing layer 303.

For the light emitting element 200R, on the planarizing layer 303, a reflecting film 304, a corrosion prevention film 305, an anode 201, a laminated body (organic EL light emitting section) 208 (208R), a cathode 207, and a cathode cover 306 are laminated in this order. In the present embodiment, the anodes 201 of each of the light emitting elements 200R, 200G, and 200B configure pixel electrodes and are electrically connected by a conductive section (wiring) 307 to drain electrodes 302e of each of the switching elements 302. In addition, the cathodes 207 of each of the light emitting elements 200R, 200G, and 200B are set as a common electrode.

In addition, it is possible for each of the configurations of the light emitting elements 200G and 200B to be configured in the same manner as the light emitting element 200R. Here, by differentiating laminated bodies 208R, 208G, and 208B (in particular, light emitting layers) of the light emitting elements 200R, 200G, and 200B from each other, it is possible to emit light of different colors. For example, the light emitting element 200R emits red light, the light emitting element 200G emits green light, and the light emitting element 200B emits blue light.

Partition walls 308 are provided between the adjacent light emitting elements 200R, 200G, and 200B. In addition, a substrate 310 is bonded with the cathode cover 306 via a resin layer 309 which is configured by a thermosetting resin such as epoxy resin.

Since each of the light emitting elements 200R, 200G, and 200B of the present embodiment described above is a top emission type, a transparent substrate is used for the substrate 310.

The constituent material of the substrate 310 is not particularly limited as long as the substrate 310 has light transmissivity, and it is possible to use the same constituent materials as the substrate 301 described above.

### Light Emitting Element

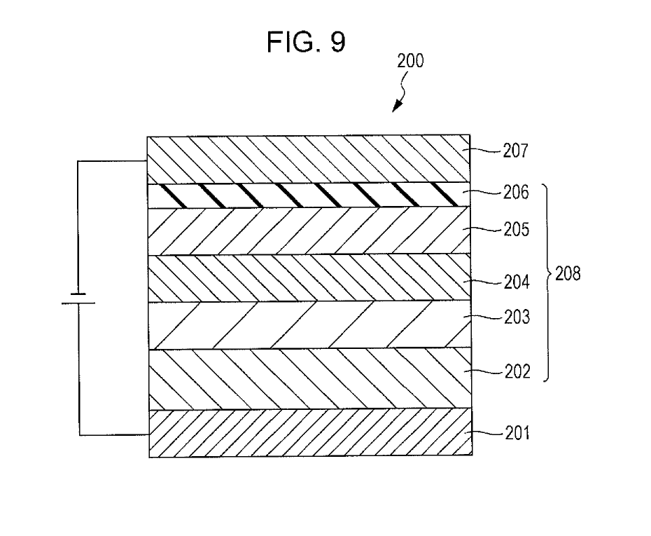

Here, based on FIG. 9, detailed description will be given of the light emitting elements 200R, 200G, and 200B.

FIG. 9 is a cross-sectional diagram of a light emitting element which is provided in the light emitting apparatus shown in FIG. 8.

The light emitting elements (electroluminescence elements) 200 shown in FIG. 9 configure the light emitting elements 200R, 200G, and 200B described above and the laminated body 208 is inserted between two electrodes as described above (between the anode 201 and the cathode 207). As shown in FIG. 9, in the laminated body 208, a hole injection layer 202, a hole transport layer 203, a light emitting layer 204, an electron transport layer 205, and an electron injection layer 206 are laminated in this order from the anode 201 side to the cathode 207 side.

In the light emitting element 200, electrons are supplied (injected) from the cathode 207 side with respect to the light emitting layer 204 and holes are supplied (injected) from the anode 201 side. Then, in each of the light emitting layers 204, the holes and electrons are recombined, excitons are generated by energy released during the recombination, and energy (fluorescent light or phosphorescent light) is released (light is emitted) when the excitons return to a ground state.

In the light emitting element 200, the hole transport layer 203 or hole injection layer 202 are formed using the film-forming method described above (the method for manufacturing the light emitting element of the invention). Due to this, it is possible to provide the light emitting element 200 and the display apparatus 300 which have excellent characteristics. Here, the light emitting element 200 may omit either of the hole injection layer 202 or the hole transport layer 203.

Below, description will be given of each of the sections which configure the light emitting element 200 in sequence.

### Anode

The anode 201 is an electrode which injects holes to the hole transport layer 203 via the hole injection layer 202 to be described below. As the constituent material of the anode 201, it is preferable to use a material with a high work function and excellent conductivity.

Examples of the constituent material of the anode 201 include oxides such as Indium Tin Oxide (ITO), Indium Zinc Oxide (IZO), In₃O₃, SnO₂, Sb-containing SnO₂, and Al-containing ZnO, Au, Pt, Ag, Cu, alloys containing these, or the like, and it is possible to use one type of the above or a combination of two or more types.

### Cathode

On the other hand, the cathode 207 is an electrode which injects electrons into the electron transport layer 205 via the electron injection layer 206 to be described below. As the constituent material of the cathode 207, it is preferable to use a material with a low work function.

Examples of the constituent material of the cathode 207 include Li, Mg, Ca, Sr, La, Ce, Er, Eu, Sc, Y, Yb, Ag, Cu, Al, Cs, and Rb, alloys containing these, or the like, and it is possible to use one type of the above or a combination of two or more types (for example, a laminated body with a plurality of layers or the like).

In particular, in a case in which an alloy is used as the constituent material of the cathode 207, it is preferable to use an alloy which includes stable metal elements such as Ag, Al, or Cu, specifically, an alloy of MgAg, AlLi, CuLi, or the like. By using the alloy as the constituent material of the cathode 207, it is possible to improve the electron injection efficiency and stability of the cathode 207.

In addition, since the light emitting element 200 of the present embodiment is a top emission type, the cathode 207 has light transmissivity.

### Hole Injection Layer

The hole injection layer 202 has a function of improving the hole injection efficiency from the anode 201.

The constituent material (the hole injection material) of the hole injection layer 202 is not particularly limited; however, examples thereof include TAPC ((1,1-bis[4-(di-p-tolyl)aminophenyl]cyclohexane)):4,4′-cyclohexylidenebis[N,N-bis(4-methylphenyl)aniline]), TPD (N,N′-diphenyl-N,N′-bis-(3-methylphenyl)-1,1′biphenyl 4,4′-diamine), α-NPD (N,N′-diphenyl-N,N′-bis-(1-naphthyl)-1,1′biphenyl-4,4′-diamine), m-MTDATA (4,4′,4″-tris(N-3-methyl-phenylamino)-triphenylamine:4,4′,4″-tris(N-3-methylphenyl-N-phenylamino)-triphenylamine), 2-TNATA (4,4′,4″-tris(N,N-(2-naphthyl)phenylamino)triphenylamine), TCTA (4,4′,4″-tri(N-carbazole group)triphenylamine:tris-(4-carbazoyl-9-yl-phenyl)-amine), TDAPB (1,3,5-tris-(N,N-bis-(4-methoxy-phenyl)-aminophenyl)-benzene:1,3,5-tris[4-(diphenylamino)phenyl]benzene), Spiro TAD, HTM1 (tri-p-tolylamineHTM2,1,1-bis[(di-4-tolylamino)phenyl]cyclohexane), HTM2 (1,1-bis[(di-4-tolylamino)phenyl]cyclohexane), TPT1 (1,3,5-tris(4-pyridyl)-2,4,6-triazin), TPTE (triphenylamine-tetramer) and the like, and it is possible to use one type of the above or a combination of two or more types.

The average thickness of the hole injection layer 202 is not particularly limited; however, approximately 5 nm to 150 nm is preferable, and approximately 10 nm to 100 nm is more preferable.

### Hole Transport Layer

The hole transport layer 203 has a function of transporting holes, which are injected from the anode 201 via the hole injection layer 202, up to the light emitting layer 204.

The constituent material of the hole transport layer 203 is not particularly limited; however, examples thereof include amine-based compounds such as triphenylamine-based polymers such as TFB (poly(9,9-dioctyl-fluorene-co-N-(4-butylphenyl)-diphenylamine)), polyfluorene derivatives (PF) poly-p-phenylene vinylene derivatives (PPV), poly-p-phenylene derivatives (PPP), polyvinyl carbazole (PVK), polythiophene derivatives, and polymeric organic materials such as polysilane-based materials including polymethyl phenyl silane (PMPS), and it is possible to use one type of the above or a combination of two or more types. In addition, it is also possible to use the constituent material of the hole injection layer 202 described above as the constituent material of the hole transport layer 203.

The average thickness of the hole transport layer 203 is not particularly limited; however, approximately 10 nm to 150 nm is preferable, and approximately 10 nm to 100 nm is more preferable.

### Light Emitting Layer

The light emitting layer 204 is configured to include a light emitting material.

The light emitting material is not particularly limited and it is possible to use various types of fluorescent materials or phosphorescent materials alone or in a combination of two or more types. In a case in which the light emitting element 200 is used as the light emitting element 200R described above, a red fluorescent material or a red phosphorescent material is used as the light emitting material, in a case in which the light emitting element 200 is used as the light emitting element 200G described above, a green fluorescent material or a green phosphorescent material is used as the light emitting material, and in a case in which the light emitting element 200 is used as the light emitting element 200B, a blue fluorescent material or a blue phosphorescent material is used as the light emitting material.

The red fluorescent material is not particularly limited as long as the material emits red fluorescent light and examples thereof include perylene derivatives such as diindenoperylene derivatives, europium complexes, benzopyran derivatives, rhodamine derivatives, benzothioxanthene derivatives, porphyrin derivatives, Nile red, 2-(1,1-dimethylethyl)-6-(2-(2,3,6,7-tetrahydro-1,1,7,7-tetramethyl-1H,5H-benzo(ij)quinolizine-9-yl)ethenyl)-4H-pyran-4H-ylidene)propanedinitrile (DCJTB), 4-(dicyanomethylene)-2-methyl-6-(p-dimethylaminostyryl)-4h-pyran (DCM), and the like.

The red phosphorescent material is not particularly limited as long as the material emits red phosphorescent light and examples thereof include metal complexes such as iridium, ruthenium, platinum, osmium, rhenium, and palladium, and at least one of the ligands of the metal complexes may have a phenylpyridine skeleton, bipyridyl skeleton, or a porphyrin skeleton, or the like. More specifically, examples thereof include tris(1-phenylisoquinoline) iridium, bis[2-(2′-benzo[4,5-α]thienyl)pyridinate-N,C^{3′}]iridium(acetylacetonate)(btp2Ir(acac)), 2,3,7,8,12,13,17,18-octaethyl-12H,23H-porphyrin-platinum (II), bis[2-(2′-benzo[4,5-α]thienyl)pyridinate-N,C^{3′}]iridium, bis(2-phenylpyridine)iridium (acetylacetonate), and the like.

The green fluorescent material is not particularly limited as long as the material emits green fluorescent light, and examples thereof include coumarin derivatives, quinacridone and derivatives thereof such as quinacridone derivatives, 9,10-bis[(9-ethyl-3-carbazole)-vinylene]-anthracene, poly(9,9-dihexyl-2,7-vinylene fluorenylene), poly[(9,9-dioctylfluorene-2,7-diyl)-co-(1,4-diphenylene-vinylene 2-methoxy-5-{2-ethylhexyl oxy}benzene)], poly[(9,9-dioctyl-2,7-di-vinylene fluorenylene)-ortho-co-(2-methoxy-5-(2-ethoxy hexyl oxy)-1,4-phenylene)], and the like.

The green phosphorescent material is not particularly limited as long as the material emits green phosphorescent light, and examples thereof include metal complexes such as iridium, ruthenium, platinum, osmium, rhenium, and palladium, specifically, fac-Tris(2-phenylpyridine) iridium (Ir(ppy)3), bis(2-phenyl-pyridinate-N,c^{2′}) iridium (acetylacetonate), fac-Tris[5-fluoro-2-(5-tri fluoro-methyl-2-pyridine)phenyl-C,N]iridium, and the like.

The blue fluorescent material is not particularly limited as long as the material emits blue fluorescent light, and examples thereof include distyrylamine derivatives such as distyryl diamine-based compounds, fluoranthene derivatives, pyrene derivatives, perylene and perylene derivatives, anthracene derivatives, benzooxazole derivatives, benzothiazole derivatives, benzimidazole derivatives, chrysene derivatives, phenanthrene derivatives, distyrylbenzene derivatives, tetraphenyl butadiene, 4,4′-bis(9-ethyl-3-carbazolvinylene)-1,1′-biphenyl (BCzVBi), poly[(9.9-dioctylfluorene-2,7-diyl)-co-(2,5-dimethoxy-benzene-1,4-diyl)], poly[(9,9-di-hexyl oxy fluorene-2,7-diyl)-ortho-co-(2-methoxy-5-{2-ethoxy hexyloxy}phenylene-1,4-diyl)], poly[(9,9-dioctylfluorene-2,7-diyl)-co-(ethylenyl benzene)], and the like.

The blue phosphorescent material is not particularly limited as long as the material emits a blue phosphorescent light, and examples thereof include metal complexes such as iridium, ruthenium, platinum, osmium, rhenium, and palladium, specifically, bis[4,6-difluorophenyl pyridinate-N,C^{2′}]-picolinate-iridium, tris[2-(2,4-difluorophenyl)pyridinate-N,C^{2′}]iridium, bis[2-(3,5-trifluoromethyl)pyridinate-N,C^{2′}]-picolinate-iridium, bis(4,6-difluorophenyl pyridinate-N,C^{2′}) iridium (acetylacetonate), and the like.

The light emitting materials may be used alone or in a combination of two or more types.

In addition, in the light emitting layer 204, host material to which the light emitting material is added as a guest material may be included in addition to the light emitting material described above.

The host material has a function of exciting the light emitting material by generating excitons by recombining holes and electrons and transferring the energy of the excitons to the light emitting material (Forster transfer or Dexter transfer). In a case in which the host material is used, for example, it is possible to use the light emitting material which is the guest material by being doped in the host material as a dopant.

The host material is not particularly limited as long as the host material exhibits functions such as described above with respect to the light emitting material to be used, and examples thereof include acene derivatives (acene-based materials) such as naphthacene derivatives, naphthalene derivatives, and anthracene derivatives, quinolinolate metal complexes such as distyrylarylene derivatives, perylene derivatives, distyrylbenzene derivatives, distyrylamine derivatives, a tris(8-quinolinolato)aluminum complex (Alq₃), triarylamine derivatives such as triphenylamine tetramers, oxadiazole derivatives, silole derivatives, dicarbazole derivatives, oligothiophene derivatives, benzopyran derivatives, triazole derivatives, benzoxazole derivatives, benzothiazole derivatives, quinoline derivatives, 4,4′-bis(2,2′-diphenyl vinyl) biphenyl (DPVBi) and the like, and it is possible to use one type of the above or a combination of two or more types.

In a case in which a red light emitting material (a guest material) and a host material are used as described above, the content (the doping amount) of the light emitting material in the light emitting layer 204 is preferably 0.01 wt % to 10 wt %, more preferably 0.1 wt % to 5 wt %. By setting the content of the red light emitting material to within the above ranges, it is possible to optimize the light emitting efficiency.

The average thickness of the light emitting layer 204 is not particularly limited; however, approximately 10 nm to 150 nm is preferable, and approximately 10 nm to 100 nm is more preferable. In addition, the light emitting layer 204 may be configured by a plurality of laminated light emitting layers, in which case an intermediate layer which does not emit light may be interposed between arbitrary light emitting layers.

### Electron Transport Layer

The electron transport layer 205 has a function of transporting electrons, which are injected from the cathode 207 via the electron injection layer 206, to the light emitting layer 204.

Examples of the constituent material (the electron transporting material) of the electron transport layer 205 include quinoline derivatives such as organic metal complexes where 8-quinolinol such as tris(8-quinolinolato)aluminum (Alq₃) or derivatives thereof are set as a ligand, oxadiazole derivatives, perylene derivatives, pyridine derivatives, pyrimidine derivatives, quinoxaline derivatives, diphenylquinone derivatives, nitro-substituted fluorene derivatives, and the like, and it is possible to use one type of the above or a combination of two or more types.

The average thickness of the electron transport layer 205 is not particularly limited; however, approximately 0.5 nm to 100 nm is preferable, and approximately 1 nm to 50 nm is more preferable.

Here, it is possible for the electron transport layer 205 to be omitted.

### Electron Injection Layer

The electron injection layer 206 has a function of improving the electron injection efficiency from the cathode 207.

Examples of the constituent material (the electron injection material) of the electron injection layer 206 include various types of inorganic insulation material, and various types of inorganic semiconductor material.

Examples of the inorganic insulation material include alkali metal chalcogenides (oxides, sulfides, selenides, tellurides), alkali earth metal chalcogenides, halides of alkali metals, halides of alkali earth metals, and the like, and it is possible to use one type of the above or a combination of two or more types. By configuring the above as the main material of the electron injection layer, it is possible further improve the electron injection property. In particular, the alkali metal compounds (the alkali metal chalcogenides and the halides of alkali metals) have a very small work function, and by configuring the electron injection layer 206 using the above, it is possible for the light emitting element 200 to obtain a high brightness.

Examples of the alkali metal chalcogenides include Li₂O, LiO, Na₂S, Na₂Se, NaO, and the like.

Examples of the alkali earth metal chalcogenides include CaO, BaO, SrO, BeO, BaS, MgO, CaSe, and the like.

Examples of the alkali metal halides include CsF, LiF, NaF, KF, LiCl, KCl, NaCl, and the like.

Examples of the alkali earth metal halides include CaF₂, BaF₂, SrF₂, MgF₂, BeF₂, and the like.

In addition, examples of the inorganic semiconductor materials include oxides, nitrides, oxynitrides, or the like containing at least one element out of Li, Na, Ba, Ca, Sr, Yb, Al, Ga, In, Cd, Mg, Si, Ta, Sb, and Zn, and it is possible to use one type of the above or a combination of two or more types.

The average thickness of the electron injection layer 206 is not particularly limited; however, approximately 0.1 nm to 1000 nm is preferable, approximately 0.2 nm to 100 nm is more preferably, and approximately 0.2 nm to 50 nm is even more preferable.

Here, it is possible to omit the electron injection layer 206.

### Electronic Equipment

FIG. 10 is a perspective diagram which shows a configuration of a portable (or a notebook) personal computer to which the electronic equipment of the invention is applied.

In the diagram, a personal computer 1100 is configured of a main body section 1104 provided with a keyboard 1102, and a display unit 1106 provided with a display section, and the display unit 1106 is supported to be able to rotate with respect to the main body section 1104 via a hinge structure section.

In the personal computer 1100, the display section provided with the display unit 1106 is configured by the display apparatus 300 described above.

FIG. 11 is a perspective diagram which shows a configuration of a mobile phone (also including PHS) to which the electronic equipment of the invention is applied.

In the diagram, a mobile phone 1200 is provided with a plurality of operation buttons 1202, an earpiece 1204, and a mouthpiece 1206, as well as a display section.

In the mobile phone 1200, the display section is configured by the display apparatus 300 described above.

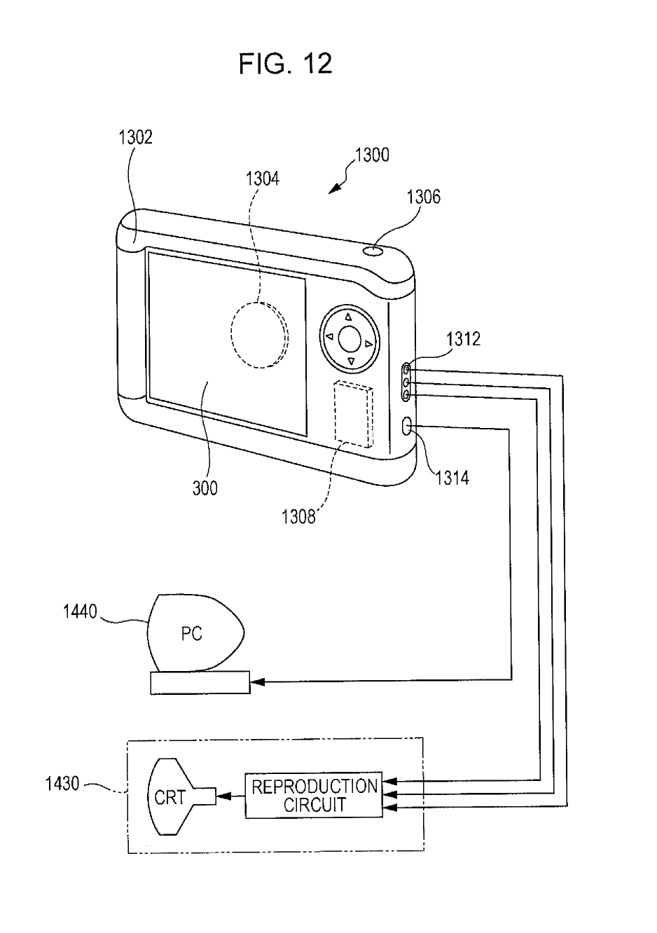

FIG. 12 is a perspective diagram which shows the configuration of a digital still camera to which the electronic equipment of the invention is applied. Here, connections with external devices are also briefly shown in the diagram.

In a regular camera, a silver salt photographic film is exposed to the optical image of a subject, while in a digital still camera 1300, an imaging signal (an image signal) is generated by photoelectric conversion of the optical image of the subject using an imaging element such as a Charged Coupled Device (CCD).

A display section is provided on the back surface of a case (body) 1302 in the digital still camera 1300 and has a configuration performing display based on an imaging signal according to the CCD and a function as a finder which displays the subject as an electronic image.

In the digital still camera 1300, the display section is configured by the display apparatus 300 described above.

A circuit board 1308 is installed inside the case. A memory which is able to save (store) an imaging signal is installed in the circuit board 1308.

In addition, a light receiving unit 1304 which includes an optical lens (an imaging optical system), a CCD, and the like is provided on the front surface side (the rear surface side in the configuration in the diagram) of the case 1302.

When a photographer confirms the subject image which is displayed on the display section and presses a shutter button 1306, an imaging signal of the CCD at that point is transferred and saved in the memory of the circuit board 1308.

In addition, in the digital still camera 1300, a video signal output terminal 1312 and an input and output terminal 1314 for data communication are provided on the side surface of the case 1302. Then, as shown in the diagram, a television monitor 1430 is connected with the video signal output terminal 1312 and a personal computer 1440 is connected with the input and output terminal 1314 for data communication as necessary. Furthermore, an imaging signal which is saved in the memory of the circuit board 1308 is configured to be output to the television monitor 1430 or the personal computer 1440 according to a predetermined operation.

The electronic equipment of the invention has excellent reliability.

Here, it is possible for the electronic equipment of the invention to be applied to, for example, televisions, video cameras, viewfinder type or a monitor-direct-view-type video tape recorders, laptop type personal computers, car navigation apparatuses, pagers, electronic notebooks (also including those having communication functions), electronic dictionaries, calculators, electronic game machines, word processors, workstations, videophones, TV security monitors, electronic binoculars, POS terminals, devices equipped with touch panels (for example, cash dispensers for financial institutions, and automatic ticket vending machines), medical devices (for example, electronic thermometers, sphygmomanometers, blood glucose meters, electrocardiogram display apparatuses, ultrasonic diagnostic apparatuses, and endoscope display apparatuses), fish finders, various types of measurement devices, gauges (for example, meters and gauges for vehicles, aircraft, and ships), flight simulators, various types of monitors, and projection type display apparatuses such as projectors in addition to the personal computer of FIG. 10 (a portable personal computer), the mobile phone of FIG. 11, and the digital still camera of FIG. 12.

Above, description was given of the film-forming ink, the discharge inspection method, the discharge inspection apparatus, the method for manufacturing a light emitting element, the light emitting element, the light emitting apparatus, and electronic equipment of the invention based on favorable embodiments in the drawings; however, the invention is not limited thereto.

For example, in the embodiment described above, description was given of a light emitting element having one light emitting layer; however, there may be two or more light emitting layers. In addition, the colors of the emitted light of the light emitting layers are not limited to R, G, and B of the embodiment described above.

In addition, in the embodiment described above, description was given of an example of a case in which the film-forming ink used in the discharge inspection method and the discharge inspection apparatus is for forming the hole transport layer or the hole injection layer; however, it is possible for the discharge inspection method and the discharge inspection apparatus of the invention to also be applied to the film-forming ink for forming a film other than the hole transport layer and the hole injection layer (for example, light emitting layers, or the like).

### EXAMPLES

Next, description will be given of specific Examples of the invention.

### 1. Preparation of Film-Farming Ink

A film-forming ink for a hole transport layer was prepared by weighing 0.45 g of TFB (poly(9,9-dioctyl-fluorene-co-N-(4-butylphenyl)-diphenylamine)) which is an amine-based compound such as a TFB triphenylamine-based polymer and 0.05 g of PtOEP (2,3,7,8,12,13,17,18-Octaethyl-21H,23H-porphine, platinum (II)) which is an indicator material (red phosphorescent material) and dissolving these in a mixed solution of 65 g of 3-phenoxytoluene and 35 g of triethyleneglycol dimethyl ether.

### 2. Manufacturing of Light Emitting Element

1. First, a transparent glass substrate with an average thickness of 0.5 mm was prepared. Next, an ITO electrode (anode) with an average thickness of 100 nm was formed on the substrate using a sputtering method.

Then, after immersing the substrate in acetone and 2-propanol in order and carrying out ultrasonic cleaning, an oxygen plasma treatment and an argon plasma treatment were carried out. These plasma treatments were each performed in a state of heating the substrate to 70 to 90° C., with a plasma power of 100 W, a gas flow rate of 20 sccm, and a treatment time of 5 sec.

2. Next, after film-forming PEDOT:PSS on the ITO electrode using a ink jet method, a hole injection layer with an average thickness of 30 nm was formed by drying and firing the result.

3. Next, the film-forming ink described above was film-formed on the hole injection layer using an ink jet method and a hole transport layer with an average thickness of 30 nm was formed by drying and firing the result.

Here, the firing was performed in a glove box filled with nitrogen, the firing temperature was set to 180° C., and the firing time was set to 30 minutes. In addition, when excitation light (ultraviolet light of 365 nm) was irradiated with respect to the obtained hole transport layer after firing, light emitted from the indicator material was not observed. Here, when the firing temperature was set to 100° C., 120° C., and 150° C. and excitation light (ultraviolet light of 365 nm) was irradiated with respect to the obtained hole transport layer after firing, light emitted from the indicator material was observed for all of the firing temperatures.

4. Next, by co-evaporating CBP which is a carbazole derivative and an IR complex which is a green light emitting material on the hole transport layer, a light emitting layer with an average thickness of 10 nm was formed.

Here, the content (the dopant concentration) of the light emitting material (the dopant) in the light emitting layer was set to 4.0 wt %.

5. Next, Alq₃ was film-formed on the light emitting layer using a vacuum deposition method and an electron transport layer with an average thickness of 80 nm was formed.

6. Next, lithium fluoride (LiF) was film-formed on the electron transport layer using a vacuum deposition method and an electron injection layer with an average thickness of 1 nm was formed.

7. Next, Al was film-formed on the electron injection layer using a vacuum deposition method. Due to this, a cathode with an average thickness of 100 nm configured by Al was formed.

According to the above processes, a light emitting element was manufactured.

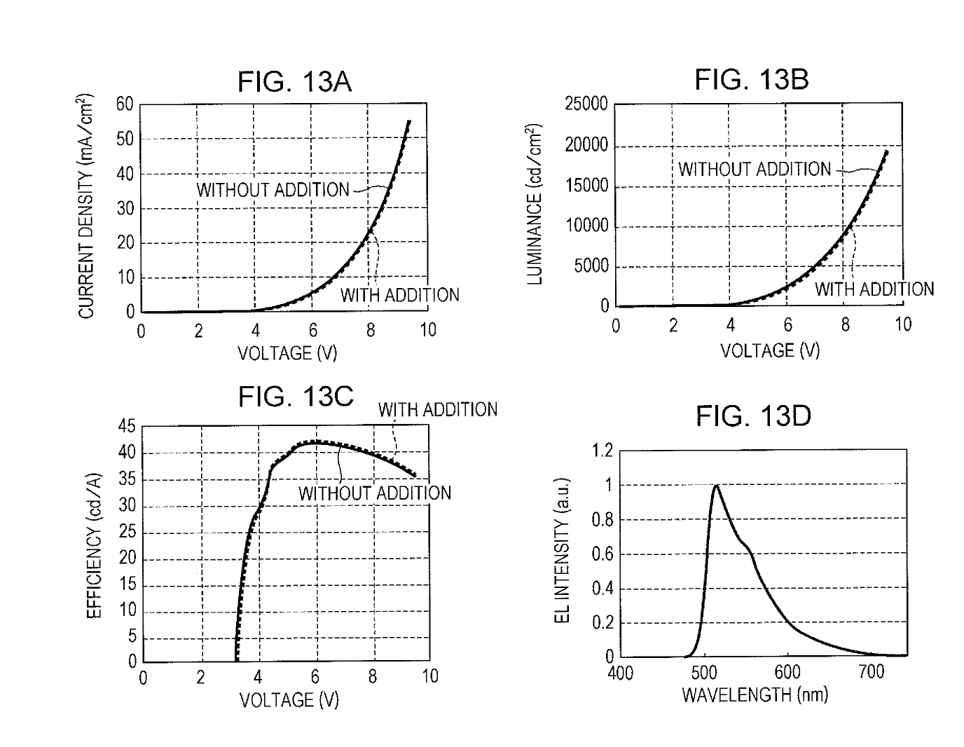

In addition, light emitting elements of Comparative Examples were manufactured in the same manner as described above apart from that the indicator material was not added to the hole transport layer. Then, when the various characteristics of the light emitting elements were measured and compared, as shown in FIGS. 13A to 13D, in the light emitting element of the invention, there was no color mixing due to the red emitted light from the indicator material and a favorable green light was emitted. In addition, it is understood that substantially the same characteristics were exhibited as the light emitting elements where the indicator material was not added to the hole transport layer (the light emitting elements of the Comparative Examples). That is, it is understood that, for the light emitting element of the invention, the light emitting function of the indicator material is eliminated due to the firing during the forming of the hole transport layer and a decrease in the characteristics of the light emitting element is not caused.

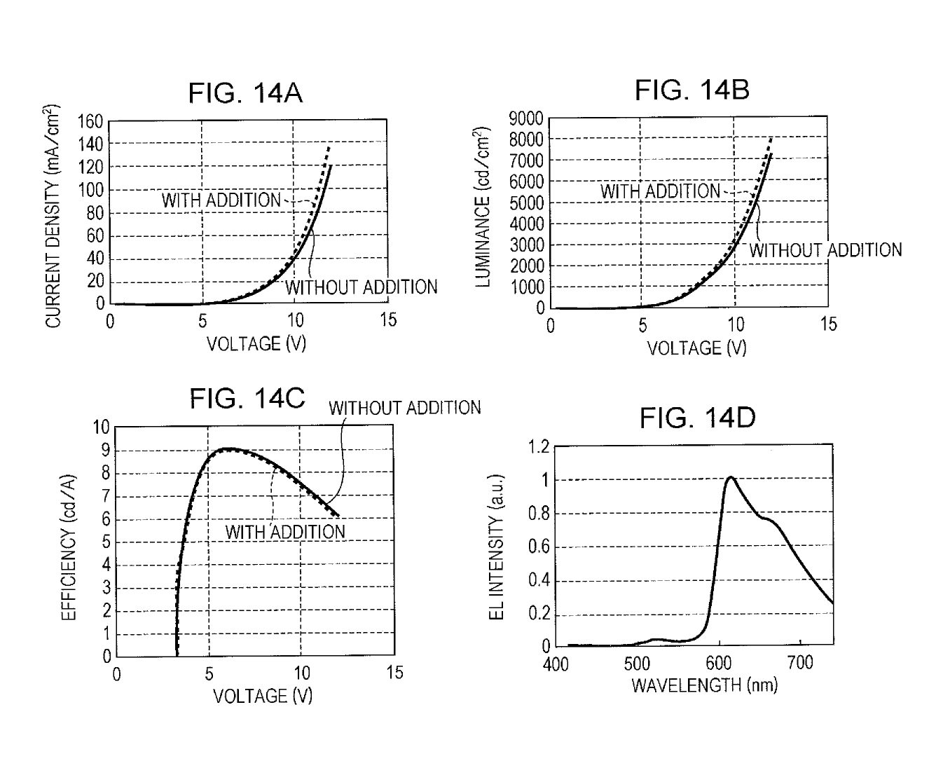

In the same manner, even in a case in which a Pt complex (red light emitting material) is used as the light emitting material of the light emitting layer, as shown in FIGS. 14A to 14D, it is understood that the light emitting element of the invention exhibits the same characteristics as the light emitting element where the indicator material is not added to the hole transport layer.

The entire disclosure of Japanese Patent Application No. 2014-027030, filed Feb. 14, 2014 is expressly incorporated by reference herein.

What is claimed is:

1. A film-forming ink comprising:
a film-forming material which is a material which configures a hole transport layer or a hole injection layer which is included in an organic electroluminescence element, or a precursor thereof; and
a liquid medium for dispersing or dissolving the film-forming material,
wherein an indicator material which emits light by being irradiated with excitation light is added to the film-forming material.

2. The film-forming ink according to claim 1,
wherein a light emitting function of the indicator material is eliminated or reduced when the hole transport layer or the hole injection layer is formed.

3. The film-forming ink according to claim 2,
wherein the light emitting function of the indicator material is eliminated or reduced due to heating.

4. The film-forming ink according to claim 1,
wherein the excitation light is ultraviolet light.

5. The film-forming ink according to claim 1,
wherein the light emitted from the indicator material is visible light or infrared light.

6. A discharge inspection method comprising:
coating a recording medium by discharging the film-forming ink according to claim 1 thereon as liquid droplets using a liquid droplet discharging head; and
irradiating the film-forming ink on the recording medium with excitation light and measuring a light emitting state of the indicator material,
wherein inspection of the liquid droplet discharging head is performed based on the measuring results.

7. A discharge inspection method comprising:
coating a recording medium by discharging the film-forming ink according to claim 2 thereon as liquid droplets using a liquid droplet discharging head; and
irradiating the film-forming ink on the recording medium with excitation light and measuring a light emitting state of the indicator material,
wherein inspection of the liquid droplet discharging head is performed based on the measuring results.

8. A discharge inspection method comprising:
coating a recording medium by discharging the film-forming ink according to claim 3 thereon as liquid droplets using a liquid droplet discharging head; and
irradiating the film-forming ink on the recording medium with excitation light and measuring a light emitting state of the indicator material,
wherein inspection of the liquid droplet discharging head is performed based on the measuring results.

9. A discharge inspection method comprising:
coating a recording medium by discharging the film-forming ink according to claim 4 thereon as liquid droplets using a liquid droplet discharging head; and
irradiating the film-forming ink on the recording medium with excitation light and measuring a light emitting state of the indicator material,
wherein inspection of the liquid droplet discharging head is performed based on the measuring results.

10. A discharge inspection method comprising:
coating a recording medium by discharging the film-forming ink according to claim 5 thereon as liquid droplets using a liquid droplet discharging head; and
irradiating the film-forming ink on the recording medium with excitation light and measuring a light emitting state of the indicator material,
wherein inspection of the liquid droplet discharging head is performed based on the measuring results.

11. A discharge inspection method comprising:
coating a recording medium by discharging a film-forming ink, which includes an indicator material which emits light by being excited with excitation light, thereon as liquid droplets using a liquid droplet discharging head; and
irradiating the film-forming ink on the recording medium with the excitation light and measuring a light emitting state of the indicator material,
wherein inspection of the liquid droplet discharging head is performed based on the measuring results.

12. The discharge inspection method according to claim 6,
wherein the recording medium has transmissivity with respect to the excitation light.

13. The discharge inspection method according to claim 6,
wherein the recording medium does not emit light due to the excitation light, or emits light at a wavelength which is different to the indicator material due to the excitation light.

14. A discharge inspection apparatus which inspects a liquid droplet discharging head which discharges the film-forming ink according to claim 1 onto a recording medium as liquid droplets, the apparatus comprising:
a light emitting section which emits the excitation light which is irradiated onto the recording medium; and
a measuring section which measures a light emitting state of the indicator material due to the excitation light on the recording medium,
wherein inspection of the liquid droplet discharging head is performed based on the measuring results of the measuring section.

15. A discharge inspection apparatus which inspects a liquid droplet discharging head which discharges film-forming ink, which includes an indicator material which emits light by being excited with excitation light, onto a recording medium as liquid droplets, the apparatus comprising:
a light emitting section which emits the excitation light which is irradiated onto the recording medium; and
a measuring section which measures a light emitting state of the indicator material due to the excitation light on the recording medium,
wherein inspection of the liquid droplet discharging head is performed based on the measuring results of the measuring section.

16. A method for manufacturing a light emitting element, the method comprising:
coating the film-forming ink according to claim 1 onto a base material; and
forming a hole transport layer or a hole injection layer by curing or solidifying the film-forming ink.

17. The method for manufacturing a light emitting element according to claim 16,
wherein the light emitting function of the indicator material is eliminated or reduced when forming the hole transport layer or the hole injection layer.

18. A light emitting element comprising:
a hole transport layer or a hole injection layer formed using the method for manufacturing a light emitting element according to claim 16.

19. A light emitting apparatus comprising:
the light emitting element according to claim 18.

20. Electronic equipment comprising:
the light emitting element according to claim 18.
